(19) United States
(12) Patent Application Publication
(10) Pub. No.: US 2013/0221812 A1
(43) Pub. Date: Aug. 29, 2013

(54) TELEVISION

(71) Applicant: KABUSHIKI KAISHA TOSHIBA, (US)

(72) Inventors: Seiji HASHIMOTO, Ome-shi (JP); Masataka TOKORO, Tachikawa-shi (JP)

(73) Assignee: KABUSHIKI KAISHA TOSHIBA, Tokyo (JP)

(21) Appl. No.: 13/711,516

(22) Filed: Dec. 11, 2012

(30) Foreign Application Priority Data
Feb. 29, 2012 (JP) 2012-043935

(51) Int. Cl. H05K 5/00

(52) U.S. Cl. CPC H05K 5/0004
USPC 312/7.2

(57) ABSTRACT

According to one embodiment, a television includes an elastic portion, a first member, and a second member. The elastic portion includes a packing and a protrusion partially on the packing. The first member includes a first portion configured to face the protrusion. The second member includes a second portion configured to face the protrusion from a side opposite to the first portion. The packing is configured to be between the first member and the second member

### CROSS-REFERENCE TO RELATED APPLICATIONS

This application is based upon and claims the benefit of priority from prior Japanese Patent Application No. 2012-043935, filed Feb. 29, 2012, the entire contents of which are incorporated herein by reference.

### FIELD

Embodiments described herein relate generally to electronic apparatuses including televisions.

### BACKGROUND

sealing structures of housings have been proposed.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view illustrating a television according to a first embodiment;

FIG. 2 is an exemplary perspective view illustrating a display unit shown in FIG. 1;

FIG. 3 is an exemplary exploded perspective view illustrating the display unit shown in FIG. 1;

FIG. 4 is an exemplary perspective view illustrating a sealing member shown in FIG. 3;

FIG. 5 is an exemplary cross-sectional view illustrating the display unit shown in FIG. 1;

FIG. 6 is an exemplary cross-sectional view illustrating the display unit shown in FIG. 1;

FIG. 7 is an exemplary plan view illustrating an inner surface of a base shown in FIG. 3;

FIG. 8 is an exemplary enlarged plan view illustrating a portion of the inner surface of the base shown in FIG. 7;

FIG. 9 is an exemplary perspective view illustrating an inner surface of a mask shown in FIG. 3;

FIG. 10 is an exemplary enlarged perspective view illustrating a portion of the inner surface of the mask shown in FIG. 9;

FIG. 11 is an exemplary exploded perspective view illustrating the display unit shown in FIG. 1;

FIG. 12 is an exemplary perspective view illustrating the attachment structure of a speaker module shown in FIG. 11;

FIG. 13 is an exemplary cross-sectional view illustrating the attachment structure of the speaker module shown in FIG. 11;

FIG. 14 is an exemplary plan view illustrating the attachment structure of the speaker module shown in FIG. 11;

FIG. 15 is an exemplary perspective view illustrating a first position of the speaker module shown in FIG. 11;

FIG. 16 is an exemplary perspective view illustrating a second position of the speaker module shown in FIG. 11;

FIG. 17 is an exemplary perspective view illustrating the speaker module shown in FIG. 11;

FIG. 18 is an exemplary flowchart illustrating a method of attaching the speaker module shown in FIG. 11;

FIG. 19 is an exemplary cross-sectional view illustrating the attachment structure related to the first embodiment;

FIG. 20 is an exemplary perspective view illustrating an electronic apparatus to which the structure according to the first embodiment may be applied;

FIG. 21 is an exemplary cross-sectional view illustrating a first position of a speaker module according to a second embodiment;

FIG. 22 is an exemplary cross-sectional view illustrating a second position of the speaker module according to the second embodiment;

FIG. 23 is an exemplary cross-sectional view illustrating a first position of a speaker module according to a third embodiment;

FIG. 24 is an exemplary cross-sectional view illustrating a second position of the speaker module according to the third embodiment;

FIG. 25 is an exemplary cross-sectional view illustrating the attachment structure of a speaker module according to a fourth embodiment;

FIG. 26 is an exemplary cross-sectional view illustrating the attachment structure of a pressing component according to a fifth embodiment;

FIG. 27 is an exemplary perspective view illustrating a television according to a sixth embodiment;

FIG. 28 is an exemplary cross-sectional view illustrating a housing taken along the line F28-F28 of FIG. 27;

FIG. 29 is an exemplary plan view illustrating the circumference of a side wall of the housing shown in FIG. 27;

FIG. 30 is an exemplary perspective view illustrating the circumference of the side wall of the housing shown in FIG. 27, as viewed from an inside of the housing;

FIG. 31 is an exemplary perspective view illustrating a method of attaching a supporting member shown in FIG. 29;

FIG. 32 is an exemplary perspective view illustrating a method of attaching a supporting member according to a seventh embodiment;

FIG. 33 is an exemplary cross-sectional view illustrating a method of attaching a supporting member according to an eighth embodiment;

FIG. 34 is an exemplary cross-sectional view illustrating a method of attaching a supporting member according to a ninth embodiment;

FIG. 35 is an exemplary exploded perspective view illustrating an exemplary electronic apparatus according to a tenth embodiment; and

FIG. 36 is an exemplary perspective view illustrating a side wall portion of the electronic apparatus shown in FIG. 35.

### DETAILED DESCRIPTION

Various embodiments will be described hereinafter with reference to the accompanying drawings.

In general, according to one embodiment, a television comprises an elastic portion, a first member, and a second member. The elastic portion comprises a packing and a protrusion partially on the packing. The first member comprises a first portion configured to face the protrusion. The second member comprises a second portion configured to face the protrusion from a side opposite to the first portion. The packing is configured to be between the first member and the second member.

Hereinafter, exemplary embodiments will be described with reference to the accompanying drawings. In the specification, the near side (e.g., user side) is defined as the front direction, the far side as viewed from the user is defined as the rear direction, the left side as viewed from the user is defined as the left direction, the right side as viewed from the user is defined as the right direction, the upper side as viewed from the user is defined as the upper direction, and the lower side as viewed from the user is defined as the lower direction. In this specification, some components which may be expressed by a plurality of terms are expressed by two or more terms. Those terms are examples. Those components may be further expressed by another or other terms. And the other components which are not expressed by two or more terms may be expressed by another or other terms.

### First Embodiment

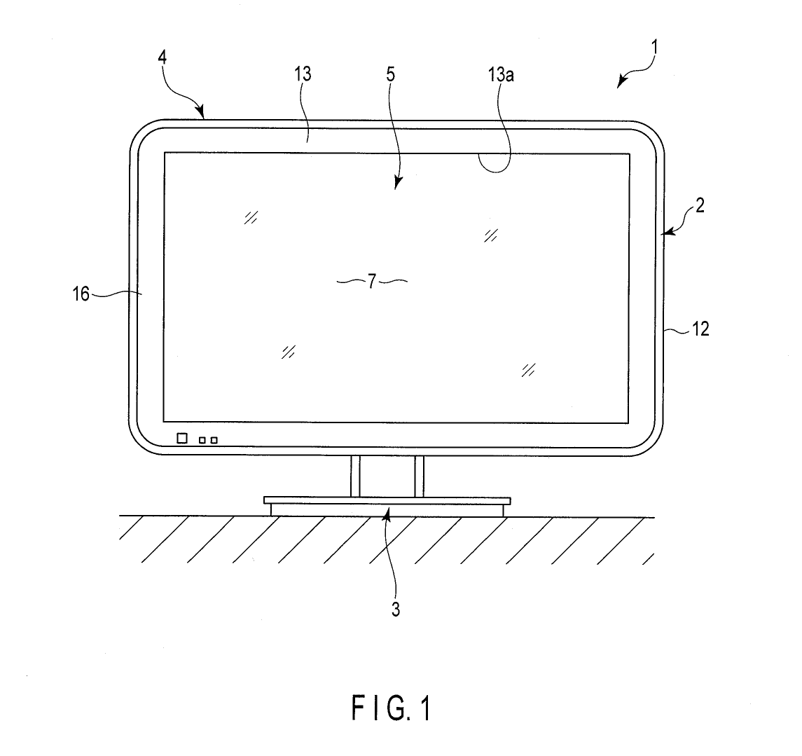

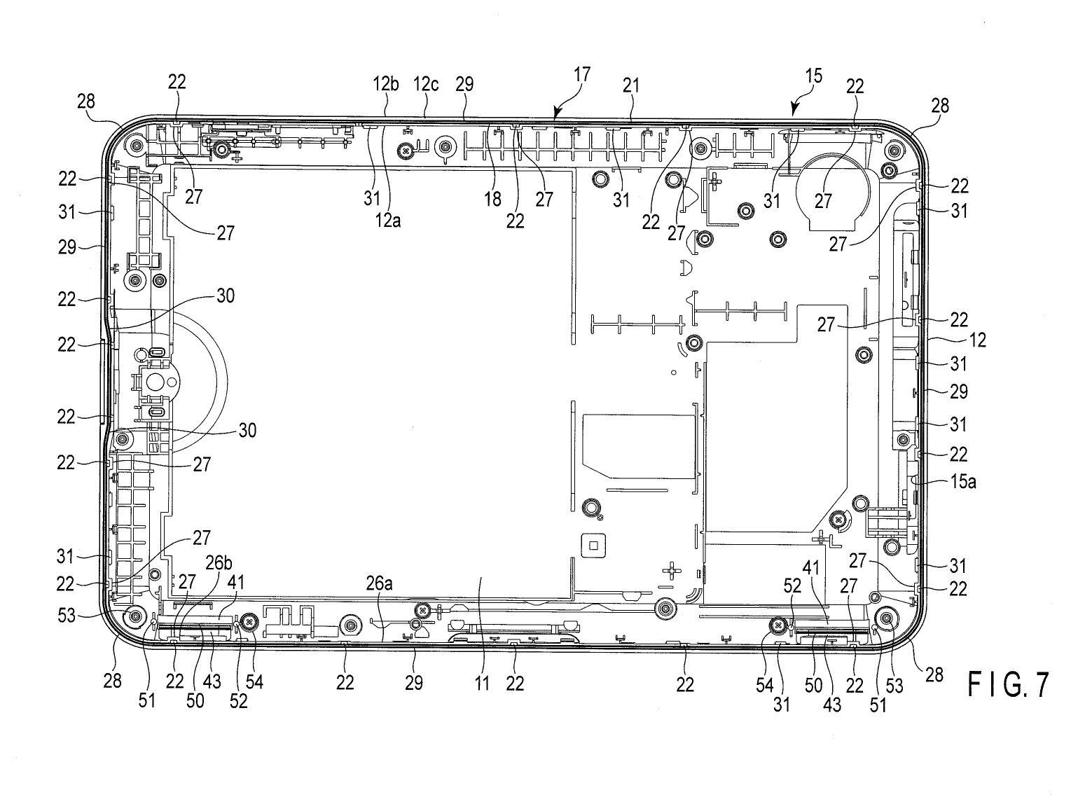

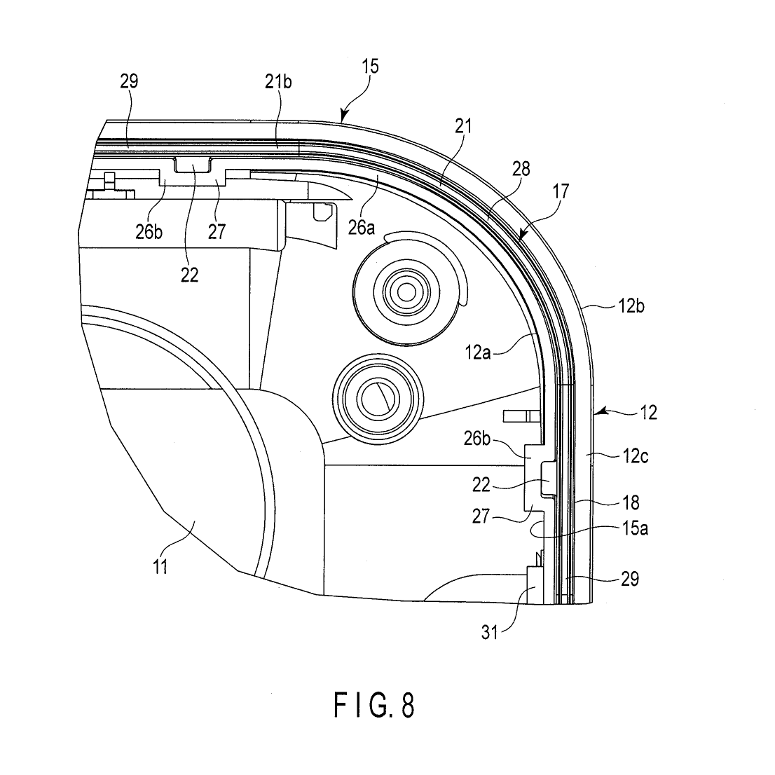

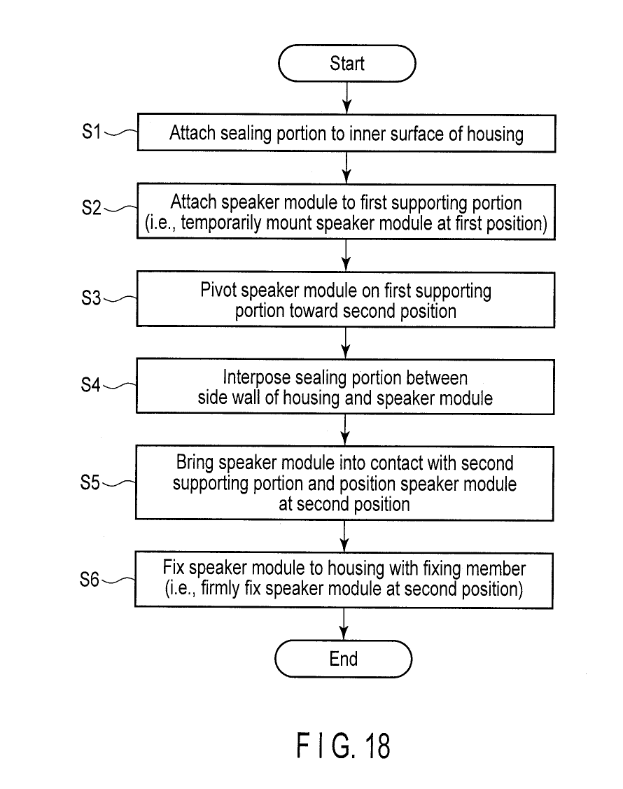

FIGS. 1 to 18 show a television 1 according to a first embodiment. The television 1 is an example of an “electronic apparatus”. The structures according to this embodiment and the following embodiments are not limited to the television, but can be widely applied to various electronic apparatuses including, for example, notebook portable computers (notebook PCs), slate portable computers (slate PCs or tablets), mobile phones (including smart phones), and game machines.

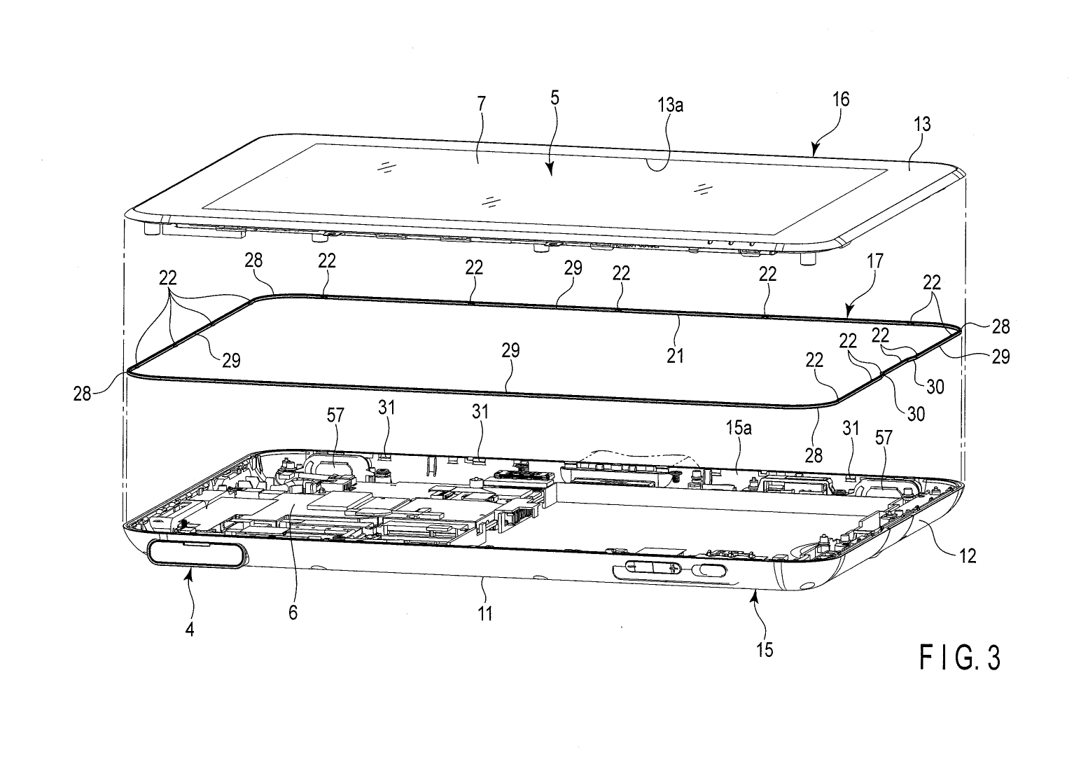

As shown in FIG. 1, the television 1 includes a display unit 2 (i.e., main unit) and a stand 3 (i.e., supporting portion) that supports the display unit 2. The display unit 2 includes a housing 4. The housing 4 includes a display device 5 and a circuit board 6 (see FIG. 3).

The display device 5 includes a first surface 5a (e.g., display surface) including a display screen 7, and a second surface 5b (e.g., rear surface) opposite to the first surface 5a. A touch sensor (i.e., touch panel) is provided on the first surface 5a. The touch sensor is an example of an input unit (i.e., an input receiving unit or an operation unit).

As shown in FIGS. 1 to 3, the housing 4 has a flat box shape including a first wall 11 (e.g., rear wall), a second wall 12 (e.g., a circumferential wall or a side wall), and a third wall 13 (e.g., front wall). The first wall 11 extends substantially in parallel to the display device 5 and the circuit board 6. The first wall 11 faces the second surface 5b of the display device 5 and the circuit board 6.

The third wall 13 is opposite to the first wall 11. The third wall 13 extends substantially in parallel to the first wall 11. The third wall 13 faces the first surface 5a of the display device 5. The display device 5 is provided between the first wall 11 and the third wall 13.

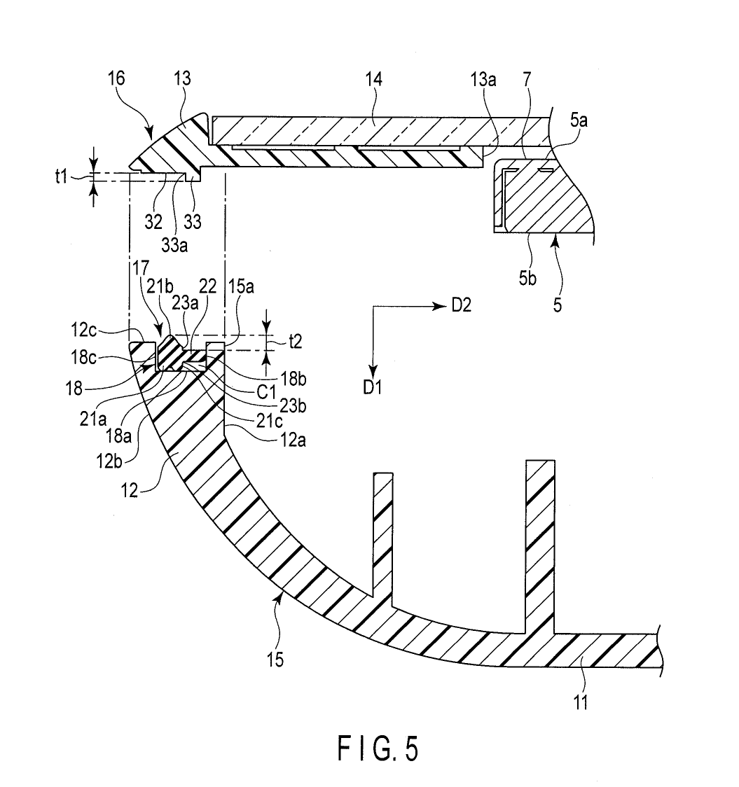

An opening 13a through which the display screen 7 is exposed is provided in the third wall 13. For example, a light-transmission panel 14 is attached to the third wall 13 (see FIG. 5). The panel 14 is, for example, a glass member or a plastic member. The panel 14 is supported by the third wall 13 and covers the opening 13a. The display screen 7 is exposed to the outside through the panel 14.

The second wall 12 extends in a direction crossing the first wall 11 and the third wall 13. The second wall 12 extends in the thickness direction of the housing 4 between the end (e.g., circumference or edge) of the first wall 11 and the end (e.g., circumference or edge) of the third wall 13. The second wall 12 is provided in the entire circumference of the first wall 11 and the third wall 13. The thickness direction of the housing 4 is from the first wall 11 to the third wall 13 (or from the third wall 13 to the first wall 11).

As shown in FIGS. 3 to 5, the third wall 13 is larger than the first wall 11. Therefore, the second wall 12 is formed in an arc shape to connect the edge of the first wall 11 and the edge of the third wall 13. The second wall 12 includes a curved surface (i.e., a surface or an outer surface) which swells to the outside of the housing 4. The second wall 12 is spread to the outside of the housing 4 in the direction from the first wall 11 to the third wall 13.

As shown in FIG. 3, the housing 4 includes a base 15 (i.e., a lower cover, a first cover, a first housing member, or a first member) and a mask 16 (i.e., an upper cover, a second cover, a second housing member, or a second member). The base 15 includes the first wall 11 and the second wall 12. The mask 16 includes the third wall 13. The mask 16 is attached to the base 15 to form the housing 4.

The base 15 has a bowl shape and is opened in a direction (e.g., the thickness direction of the housing 4 or a side opposite to the first wall 11) crossing the first wall 11. The inner circumferential surface (i.e., an inner surface 12a which will be described below) of the second wall 12 defines an opening 15a through which an inside of the base 15 is exposed to the outside.

As shown in FIG. 3, in the assembly of the display unit 2, the first wall 11 of the base 15 is placed on an external mounting surface (e.g., an assembly table), components are attached to the inside of the base 15, and the mask 16 is attached to the base 15. Therefore, the first wall 11 may be referred to as a “lower wall” or a “bottom wall”. The third wall 13 may be referred to as an “upper wall”. In the following description, for convenience of explanation, the first wall 11 is referred to as the bottom wall 11, the second wall 12 is referred to as the side wall 12, and the third wall 13 is referred to as the upper wall 13.

The television 1 according to this embodiment has, for example, a waterproof property. Therefore, the television 1 has the following various structures in order to have a waterproof property. The purpose of these structures is not limited to waterproofing, but these structures may be used for other purposes.

(Sealing Structure of Housing)

First, the sealing structure of the housing 4 will be described. As shown in FIG. 3, a sealing member 17 (e.g., an elastic portion, an elastic member, an interposed member, a blocking member, a packing, a member, or a component) is provided between the base 15 and the mask 16. An example of the sealing member 17 is a gasket (e.g., case gasket). The sealing member 17 is made of, for example, rubber. The sealing member 17 is interposed (e.g., compressed or deformed) between the base 15 and the mask 16 and liquid-tightly seals a space (e.g., clearance) between the base 15 and the mask 16.

Specifically, as shown in FIGS. 3 to 5, the side wall 12 of the housing 4 includes an inner surface 12a (i.e., an inner circumferential surface or a first surface), an outer surface 12b (i.e., a surface, an outer circumferential surface, or a second surface), and an attachment surface 12c (i.e., a connection surface, a supporting surface, or a third surface). The inner surface 12a is exposed to the inside of the housing 4. The outer surface 12b is opposite to the inner surface 12a and is exposed to the outside of the housing 4.

The attachment surface 12c extends between the inner surface 12a and the outer surface 12b in a direction crossing the inner surface 12a and the outer surface 12b. The attachment surface 12c is substantially parallel to the first wall 11. The attachment surface 12c faces the end (e.g., circumference or edge) of the mask 16. That is, the attachment surface 12c faces the end of the mask 16 in a direction crossing (e.g., substantially perpendicular to) the first wall 11. The attachment surface 12c comes into contact with the end of the mask 16 and supports the end of the mask 16.

The attachment surface 12c is provided in, for example, the entire circumference of the base 15. A groove 18 (i.e., an attachment portion, a supporting portion, a holding portion, an accommodating portion, an engaging portion, or a recess) to which the sealing member 17 is attached is provided in the attachment surface 12c. The groove 18 faces the end of the mask 16 and is covered by the mask 16. The groove 18 is provided in, for example, the entire circumference of the base 15 and has an annular shape (e.g., frame shape) along the circumference (e.g., edge) of the base 15. The groove 18 is disposed outside the opening 15a and surrounds the opening 15a.

As shown in FIG. 5, the groove 18 includes a lower surface 18a (e.g., a bottom surface, a supporting surface, an attachment surface, a deep portion, or a first surface), a first side surface 18b (e.g., a first rising surface, a first circumferential surface, or a second surface), and a second side surface 18c (e.g., a second rising surface, a second circumferential surface, or a third surface). The lower surface 18a is substantially parallel to the attachment surface 12c. The lower surface 18a includes a first end and a second end opposite to the first end. The first side surface 18b rises from the first end of the lower surface 18a and connects the first end of the lower surface 18a and the attachment surface 12c. The second side surface 18c rises from the second end of the lower surface 18a and connects the second end of the lower surface 18a and the attachment surface 12c.

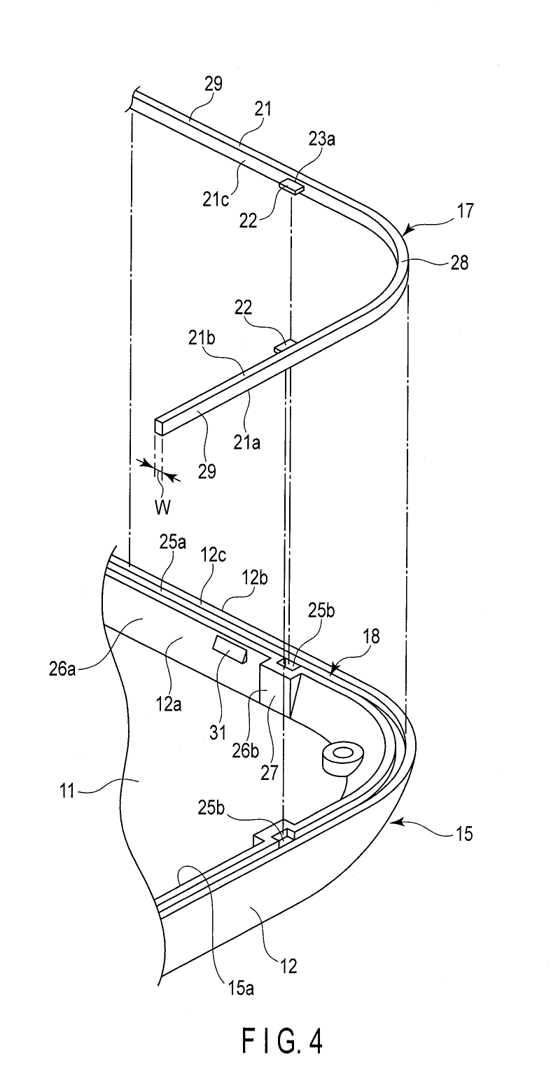

As shown in FIGS. 3 and 4, the sealing member 17 has a shape corresponding to the groove 18. That is, the sealing member 17 has an annular shape (e.g., frame shape) along the circumference (e.g., edge) of the base 15. The sealing member 17 is attached to the groove 18. The sealing member 17 is disposed outside the opening 15a and surrounds the opening 15a.

As shown in FIGS. 3 to 5, the sealing member 17 includes a packing portion 21 (i.e., an interposed portion, a blocking portion, a closing portion, a compressing portion, or a first portion) and a plurality of protruding portions 22 (i.e., protrusions, sword portions, extension portions, supporting portions, or second portions). At least a portion of the packing portion 21 extends linearly. The packing portion 21 forms the body of the sealing member 17 and has an annular shape (e.g., frame shape) along the circumference of the base 15.

The packing portion 21 is disposed outside the opening 15a and surrounds the opening 15a. The packing portion 21 is interposed between the base 15 and the mask 16 and is compressed (e.g., deformed) between the base 15 and the mask 16. The packing portion 21 liquid-tightly seals the space between the base 15 and the mask 16.

As shown in FIG. 5, the packing portion 21 has a cross-section closer to a pentagon than a circle. The packing portion 21 includes a first end 21a and a second end 21b in the thickness direction thereof. The first end 21a faces the lower surface 18a of the groove 18 and comes into contact with the lower surface 18a of the groove 18. The second end 21b is opposite to the first end 21a. The second end 21b faces the mask 16 and comes into contact with the mask 16.

As shown in FIG. 5, the first end 21a includes two projections and a recess which is provided between the two projections. The two projections come into contact with the lower surface 18a of the groove 18 and are supported by the lower surface 18a of the groove 18. Since the recess is provided between the two projections, the two projections are likely to be elastically deformed. Therefore, the first end 21a is likely to come into close contact with the lower surface 18a of the groove 18, which improves the liquid-tightness (e.g., waterproof performance) of the television 1.

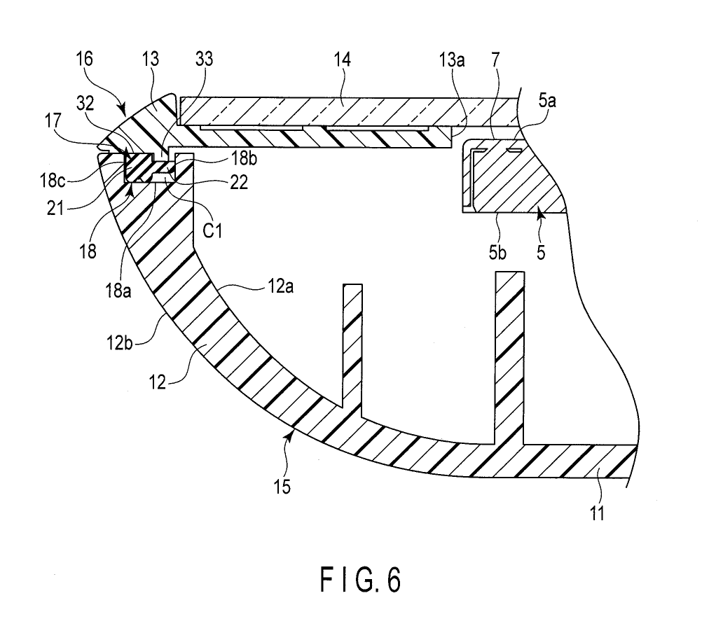

The second end 21b has a wedge shape (i.e., mountain shape) before compressive deformation. That is, the second end 21b is tapered toward the mask 16. As shown in FIG. 6, the second end 21b comes into contact with the mask 16 and is supported by the mask 16. The second end 21b is pressed by the mask 16 and is deformed (e.g., elastically deformed) along the inner surface of the mask 16. In this way, a space between the second end 21b and the mask 16 is reliably liquid-tightly sealed. Since the second end 21b has a wedge shape, it is likely to be elastically deformed. Therefore, the second end 21b is likely to come into contact with the mask 16, which improves the liquid-tightness (e.g., waterproof performance) of the television 1.

As shown in FIGS. 3 and 4, the protruding portions 22 are partially provided in the packing portion 21. A plurality of protruding portions 22 are separated from each other in the direction (e.g., the circumferential direction of the packing portion 21) in which the packing portion 21 extends.

As shown in FIG. 5, the packing portion 21 includes a side surface 21c (e.g., an inner circumferential surface or an inner surface) which extends between the first end 21a and the second end 21b. The side surface 21c faces the first side surface 18b of the groove 18. The protruding portions 22 are provided on the side surface 21c and protrude from the side surface 21c toward the inside of the packing portion 21. Each of the protruding portion 22 extends in a plate shape in a direction substantially parallel to the lower surface 18a of the groove 18.

The direction (e.g., the thickness direction of the housing 4) in which the mask 16 is attached to the base 15 is defined as a first direction D1. The direction crossing (e.g., substantially perpendicular to) the first direction D1 is defined as a second direction D2. The protruding portion 22 protrudes in the second direction D2.

As shown in FIG. 5, the protruding portions 22 protrude from substantially the center of the side surface 21c. A first step portion 23a is provided between the protruding portion 22 and the second end 21b. Therefore, the protruding portion 22 is closer to the lower surface 18a of the groove 18 than the second end 21b. The protruding portion 22 is closer to the first end 21a than the second end 21b. In other words, the protruding portion 22 is further away from the attachment surface 12c (or mask 16) than the second end 21b.

A second step portion 23b is provided between the protruding portion 22 and the first end 21a. Therefore, the protruding portion 22 is closer to the mask 16 than the first end 21a. The protruding portion 22 is closer to the second end 21b than the first end 21a. In other words, the protruding portion 22 is further away from the lower surface 18a of the groove 18 than the first end 21a. A gap C1 is provided between the protruding portion 22 and the lower surface 18a of the groove 18.

When the sealing member 17 (e.g., packing portion 21) is twisted or falls during the attachment of the sealing member 17 to the groove 18, the protruding portion 22 comes into contact with the lower surface 18a of the groove 18. In this way, the sealing member 17 (e.g., packing portion 21) may be prevented from being greatly twisted or falling.

As shown in FIG. 4, the groove 18 includes a first portion 25a and second portions 25b. The first portion 25a is provided so as to correspond to the outward shape of the packing portion 21 and the packing portion 21 is accommodated in the first portion 25a. Each of the second portion 25b corresponds to the protruding portion 22. The second portion 25b is provided so as to correspond to the outward shape of the protruding portion 22 and the protruding portion 22 is accommodated in the second portion 25b. The lower surface 18a of the groove 18 disposed in the second portion 25b is an example of a “first portion facing a protruding portion”.

The side wall 12 includes first regions 26a (i.e., first portions) and second regions 26b (i.e., second portions). The first regions 26a correspond to portions in which the protruding portions 22 are not provided. The first regions 26a extend substantially in parallel to the packing portion 21. The second regions 26b correspond to the protruding portions 22, respectively. Each of the second regions 26b includes a raised portion 27 (an extension portion or a protruding portion) which protrudes to the inside of the housing 4, as compared to the first regions 26a. In this way, the attachment surface 12c of the second region 26b is larger than the attachment surface 12c of the first region 26a. The second portion 25b of the groove 18 is provided on the attachment surface 12c of the second region 26b with a large width.

As shown in FIG. 3, the packing portion 21 includes four corners 28 (i.e., corner portions, arc portions, or curved portions) and four straight portions 29 which extend between the four corners 28. In addition, the packing portion 21 includes bent portions 30 which are provided in one straight portion 29 and is bent to the inside of the housing 4.

Each of the corners 28 and the bent portions 30 is an example of a path-changed portion (i.e., non-straight portion) which is changed from the straight shape of the packing portion 21. A plurality of protruding portions 22 are separately disposed on both sides of the path-changed portion. In other words, the path-changed portion is disposed between the plurality of protruding portions 22. In addition, some of the protruding portions 22 are provided in the straight portions 29. The protruding portion 22 may be provided at the corner 28 or in the bent portion 30.

As shown in FIG. 4, engaging portions 31 (receiving portions, claw portions, supporting portions, or attachment portions) to which the mask 16 is fitted are provided on the inner surface 12a of the side wall 12. For example, the protruding portion 22 is provided in the vicinity of one of the engaging portions 31. The engaging portions 31 are provided in the first regions 26a (i.e., regions in which the raised portion 27 are not provided) of the side wall 12.

The engaging portions 31 are arranged in a line with the raised portions 27 in a direction substantially parallel to (e.g., along the inner surface 12a) the inner surface 12a of the side wall 12. In other words, a part of the engaging portion 31 is closer to the outer surface 12b of the side wall 12 than a part of the raised portion 27. Since the engaging portions 31 and the raised portions 27 are provided in different regions of the side wall 12, it is possible to reduce the thickness of the side wall 12, which contributes to reducing the size of the television 1.

As shown in FIGS. 5, 6, 9, and 10, the inner surface of the mask 16 includes a planar portion 32 (i.e., a pressing portion, a contact portion, a connection portion, or a first portion) and a plurality of supporting portions 33 (i.e., protrusions, protruding portions, supporting portions, or second portions). The planar portion 32 is provided in the entire circumference of the mask 16. The planar portion 32 faces the packing portion 21 and comes into contact with the packing portion 21. The planar portion 32 presses the packing portion 21 to the lower surface 18a of the groove 18 and supports the packing portion 21. In this way, the packing portion 21 is compressed between the planar portion 32 and the lower surface 18a of the groove 18.

The supporting portions 33 are partially provided at positions corresponding to the protruding portions 22 of the sealing member 17. The plurality of supporting portions 33 are separately provided in the circumference of the mask 16 in the circumferential direction. The supporting portion 33s are protrusions (e.g., ribs) which are provided on the inner surface of the mask 16, for example. The supporting portions 33 project from the mask 16 to the protruding portions 22 and face the protruding portions 22, respectively. The supporting portions 33 face the protruding portions 22 from the side opposite to the lower surface 18a of the groove 18. Each of the supporting portion 33 is an example of a “second portion facing a protruding portion”. The leading ends of the supporting portions 33 are inserted into the groove 18 and face the protruding portions 22 in the groove 18.

As shown in FIG. 5, a third step portion 33a is provided between the supporting portions 33 and the planar portion 32. The step width t1 (i.e., thickness) of the third step portion 33a is less than the step width t2 (i.e., thickness) of the first step portion 23a of the sealing member 17.

As shown in FIG. 6, the supporting portions 33 are slightly separated from the protruding portions 22 or they come into light contact with the protruding portions 22. The supporting portion 33 faces the protruding portion 22 to regulate the twist or falling of the sealing member 17 (e.g., packing portion 21). That is, when the sealing member 17 is twisted or falls and the protruding portion 22 is moved in the direction in which it is separated from the lower surface 18a of the groove 18, the supporting portion 33 presses the protruding portion 22 to suppress the twist or falling of the sealing member 17 (e.g., packing portion 21). The supporting portion 33 suppresses the twist or falling of the sealing member 17 (e.g., packing portion 21) between the mask 16 and the base 15 when the mask 16 is attached to the base 15.

According to this structure, it is possible to improve the assemblability of an electronic apparatus.

The sealing member interposed between the base and the mask is deformed (e.g., compressed and deformed) between the mask and the base when the mask is attached to the base. In this way, the liquid-tight connection between the mask and the base is ensured.

When the mask is vertically attached to the base, the sealing member is not twisted or does not fall. However, it is assumed that the mask is obliquely attached to the base according to an assembly error or the learning level of the operator. In this case, the sealing member is likely to be twisted or fall between the mask and the base. When the sealing member is twisted or falls, the sealing member is not appropriately deformed and the sufficient performance of the sealing member is not likely to be obtained.

In this embodiment, the sealing member 17 of the television 1 includes the packing portion 21 and the protruding portions 22 which are partially provided in the packing portion 21. The base 15 includes the first portion (e.g., the lower surface 18a of the groove 18) facing the protruding portion 22. The mask 16 includes the second portion (e.g., the supporting portion 33) which faces the protruding portion 22 from the side opposite to the first portion. According to this structure, the protruding portions 22 are supported by the base 15 or the mask 16 and the packing portion 21 is less likely to be rotated. In this way, the twist or falling of the sealing member 17 is suppressed and it is possible to improve the assemblability of the television 1.

In addition, when the supporting portion 33 is provided, the sealing member 17 is less likely to be twisted or fall even though the width W (e.g., horizontal width) (see FIG. 4) of the packing portion 21 is small (i.e., thin). Therefore, it is possible to use the sealing member 17 with a small width W, which contributes to reducing the size of the television 1.

In this embodiment, the mask 16 includes the supporting portion 33 which faces the protruding portion 22 from the side opposite to the base 15. According to this structure, the protruding portion 22 is supported by the supporting portion 33 and the rotation of the packing portion 21 is regulated. In this way, it is possible to prevent the twist or falling of the sealing member 17.

In this embodiment, the protruding portion 22 is provided on the inner surface of the annular packing portion 21. Therefore, it is possible to arrange the raised portion 27 and the engaging portion 31 in a substantially straight line shape along the inner surface 12a of the side wall 12. In this way, it is possible to reduce the size of the television 1.

In this embodiment, the gap C1 is provided between the protruding portion 22 and the lower surface 18a of the groove 18. According to this structure, it is possible to prevent the insufficient compression of the packing portion 21 between the mask 16 and the base 15 due to the protruding portion 22 interposed between the mask 16 and the base 15. That is, the gap C1 (e.g., clearance or allowance) between the protruding portion 22 and the lower surface 18a of the groove 18 makes it possible to appropriately compress the packing portion 21 between the mask 16 and the base 15.

In this embodiment, the protruding portion 22 is closer to the lower surface 18a of the groove 18 than the second end 21b of the packing portion 21. That is, the step portion 23a is provided between the second end 21b of the packing portion 21 and the protruding portion 22. According to this structure, it is possible to reliably prevent the insufficient compression of the packing portion 21 between the mask 16 and the base 15 due to the protruding portion 22 interposed between the planar portion 32 of the mask 16 and the base 15.

In this embodiment, the leading end of the supporting portion 33 is inserted into the groove 18 and faces the protruding portion 22 in the groove 18. According to this structure, when the sealing member 17 is twisted or falls, the supporting portion 33 can reliably press the protruding portion 22.

In this embodiment, the second end 21b of the packing portion 21 has a wedge shape which is tapered toward the mask 16. According to this shape, the second end 21b is likely to be elastically deformed and the second end 21b and the mask 16 are likely to come into close contact with each other.

When the second end 21b has a wedge shape and the mask 16 is obliquely attached to the base 15, the sealing member 17 is likely to be twisted or fall. However, according to this embodiment, since the supporting portion 33 supports the protruding portion 22, it is possible to suppress the sealing member 17 from being twisted or falling. In other words, since the protruding portion 22 and the supporting portion 33 are provided, it is possible to bring the mask 16 into close contact with the packing portion 21 while preventing the twist or falling of the sealing member, even when the second end 21b has a wedge shape.

In this embodiment, a plurality of protruding portions 22 are separately disposed on both sides of the path-changed portion of the packing portion 21. According to this structure, it is possible to reliably support the path-changed portion which is particularly likely to be twisted or fall. In addition, since the protruding portions 22 are provided on both sides of the path-changed portion, not in the path-changed portion, a housing structure, such as a boss, can be provided in the vicinity of the path-changed portion (e.g., the corner 28), which contributes to reducing the size of the television 1.

In this embodiment, the protruding portions 22 and the supporting portions 33 are partially provided in the circumference of the base 15. In this way, the engaging portions 31 (i.e., connection portions) for connecting the base 15 and the mask 16 can be provided in regions (e.g., the regions 26a) in which the protruding portions 22 and the supporting portions 33 are not provided. Therefore, according to the structure of this embodiment, it is possible to reduce the size of the television 1, as compared to a case in which the protruding portions 22 and the supporting portions 33 are provided in the entire circumference of the base 15.

The television 1 is not limited to the above-mentioned structure. For example, the sealing member 17 may be attached to the mask 16, instead of the base 15. That is, the groove 18 may be provided in the mask 16, the sealing member 17 is attached to the groove 18, and the supporting portion 33 may be provided in the base 15. In this case, the mask 16 is an example of a “first member”. The base 15 is an example of a “second member”. The attachment portion to which the sealing member 17 is attached may not be a groove. The sealing member 17 is not limited to the annular shape.

In this embodiment, the protruding portion 22 extends in a direction substantially parallel to the lower surface 18a of the groove 18, but the embodiments are not limited thereto. For example, the protruding portion 22 may extend in a direction crossing the lower surface 18a. The protruding portion 22 may protrude from the outer circumferential surface of the packing portion 21 to the outside. The shape or structure of the packing portion 21, the protruding portion 22, and the supporting portion 33 is not limited to the above.

(Speaker Attachment Structure)

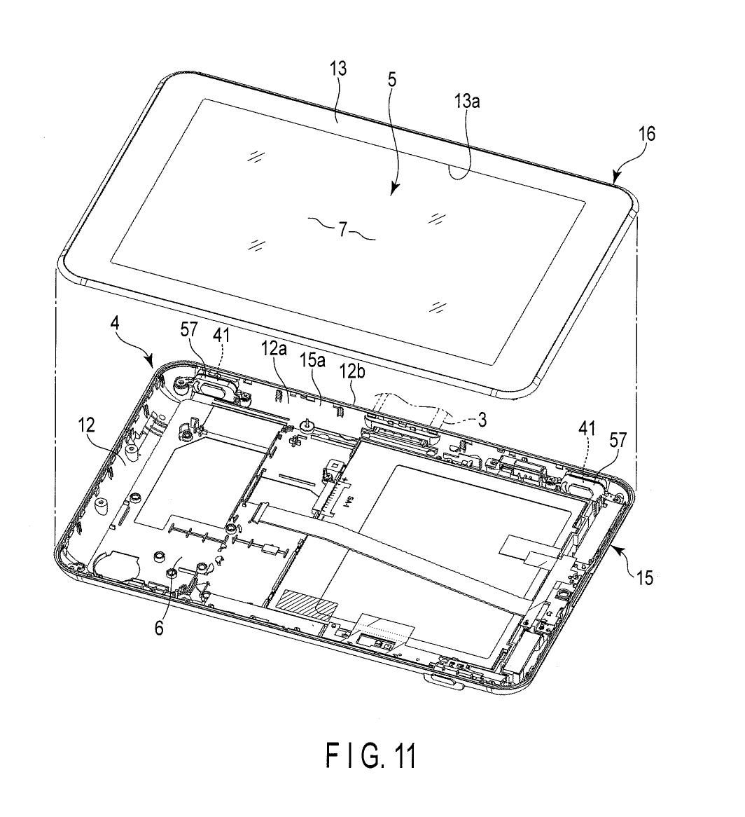

Next, a speaker attachment structure will be described. As shown in FIG. 11, a pair of speakers 41 are provided in the housing 4. Since the pair of speakers 41 have substantially the same attachment structure, the attachment structure of one speaker 41 will be representatively described in detail.

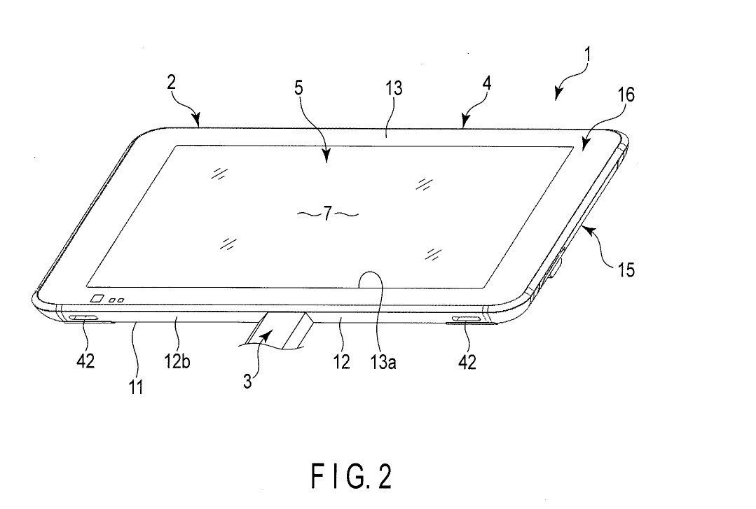

As shown in FIGS. 2, 12, and 13, An opening 42 is provided in the side wall 12 of the housing 4. The opening 42 is a sound emitting portion (e.g., sound emitting opening) through which a sound from the speaker 41 is emitted. The opening 42 is provided substantially in parallel to the bottom wall 11 and is laterally formed in the side wall 12. As shown in FIGS. 11 to 13, the speaker 41 faces the opening 42 in the housing 4.

An attachment portion 43 (e.g., raised portion) to which the speaker 41 is attached is provided on the inner surface 12a of the side wall 12 of the housing 4. The attachment portion 43 protrudes from the inner surface 12a of the side wall 12 to the inside of the housing 4. In this way, the attachment portion 43 includes an attachment surface 43a which extends in the thickness direction of the housing 4. That is, the attachment surface 43a extends in a direction crossing the arc-shaped side wall 12. The opening 42 (e.g., sound emitting opening) is provided in the attachment portion 43 and the attachment portion 43 is provided integrally with the side wall 12.

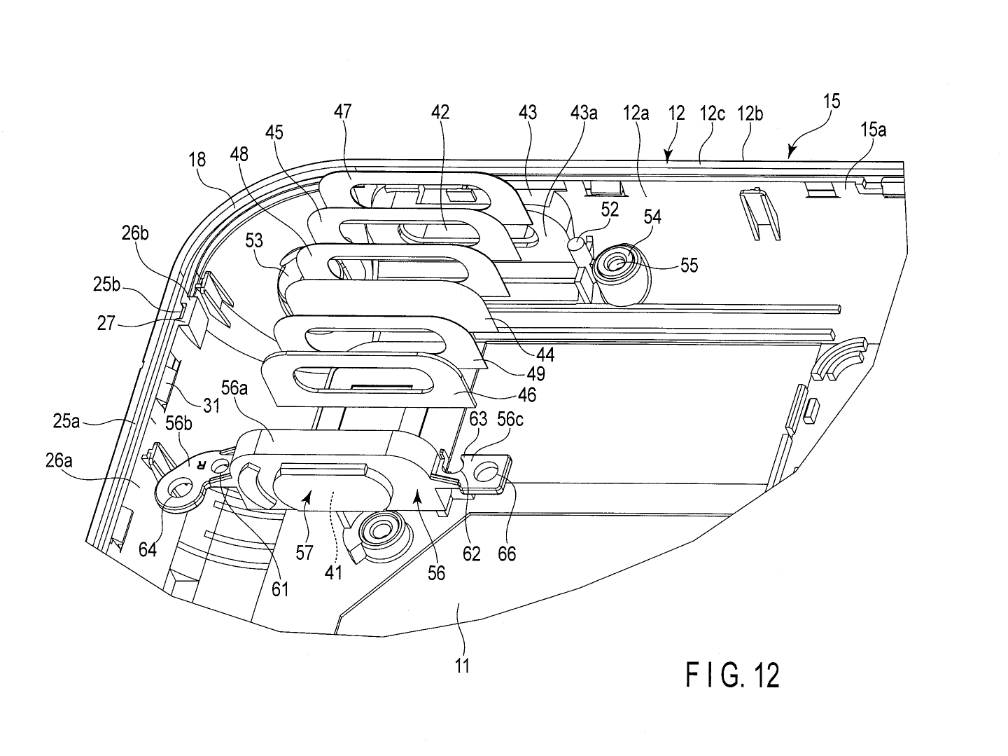

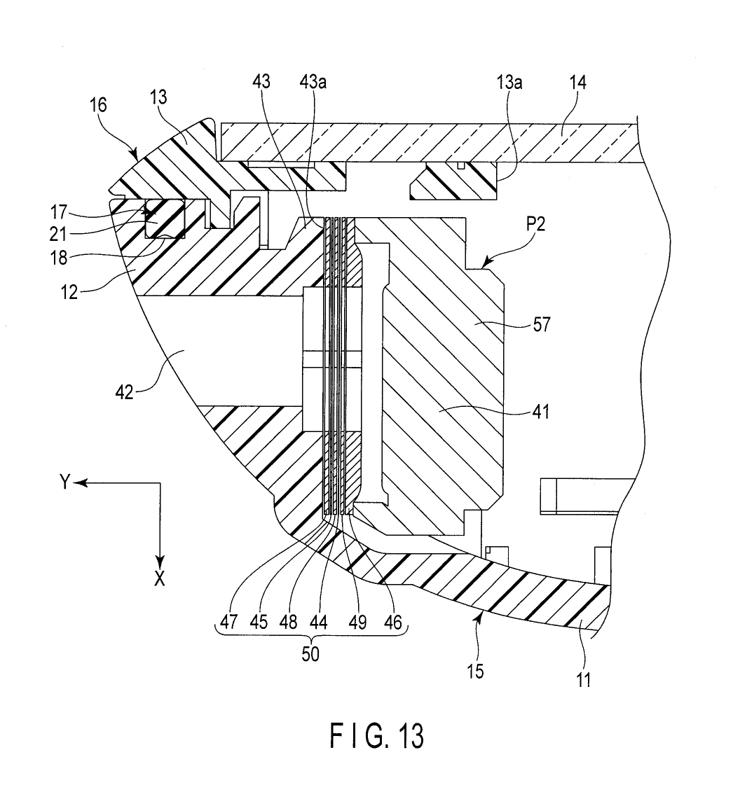

As shown in FIGS. 12 and 13, a waterproof sheet 44, two cushions 45 and 46, and three double-sided tapes 47, 48, and 49 are provided between the speaker 41 and the opening 42 (e.g., side wall 12). The waterproof sheet 44 (e.g., liquid-tight sheet, a waterproof portion, a blocking portion, a shielding portion, a sheet, or a member) is disposed between the attachment surface 43a and the speaker 41. No hole is provided in the waterproof sheet 44. The waterproof sheet 44 is made of a relatively hard material in order to transmit vibration from the speaker 41 to the outside.

The first cushion 45 (i.e., a first elastic portion or a first interposed member) is provided between the waterproof sheet 44 and the attachment surface 43a. The second cushion 46 (i.e., a second elastic portion or a second interposed member) is provided between the waterproof sheet 44 and the speaker 41. The cushions 45 are 46 are members which can be pressed and deformed and are, for example, sponge members or rubber members. The cushions are provided on both sides of the waterproof sheet 44 such that the waterproof sheet 44 can be vibrated in the front-rear direction. Each of the first and second cushions 45 and 46 includes an opening corresponding to the opening 42 (e.g., sound emitting opening).

The first waterproof double-sided tape 47 is provided between the first cushion 45 and the attachment surface 43a. The second waterproof double-sided tape 48 is provided between the first cushion 45 and the waterproof sheet 44. The third double-sided tape 49 is provided between the waterproof sheet 44 and the second cushion 46. Each of the first to third double-sided tapes 47, 48, and 49 includes an opening corresponding to the opening 42 (e.g., sound emitting opening).

The waterproof sheet 44, the cushions 45 and 46, and the double-sided tapes 47, 48, and 49 are bonded to each other. Before the speaker 41 is attached, the bonded structure is attached to the attachment surface 43a and is supported by the housing 4. The waterproof sheet 44, the cushions 45 and 46, and the double-sided tapes 47, 48, and 49 which are bonded to each other to form one body are an example of a sealing portion 50. The sealing portion 50 is an example of an “elastic portion”.

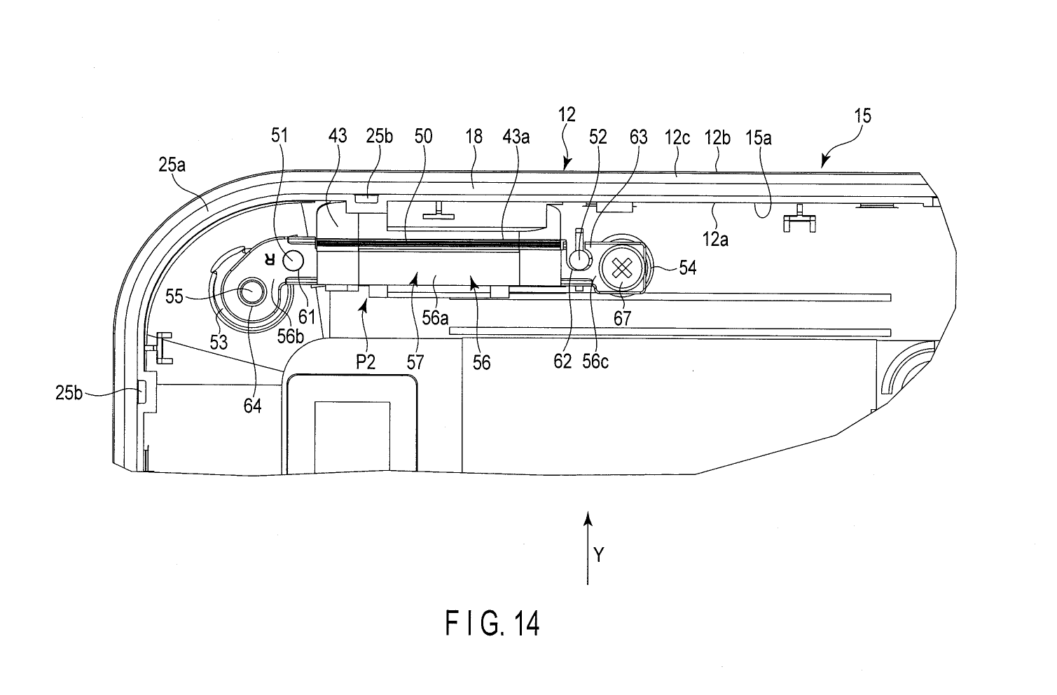

As shown in FIGS. 14 to 16, the housing 4 includes a first supporting portion 51 (i.e., a first protrusion, a first attachment portion, a first temporary engaging portion, or a first temporary fixing portion) and a second supporting portion 52 (i.e., a second protrusion, a second attachment portion, a second temporary engaging portion, or a second temporary fixing portion). Each of the first supporting portion 51 and the second supporting portion 52 is a protrusion which protrudes from the inner surface of the housing 4 and is, for example, a cylindrical pin. For example, the first supporting portion 51 and the second supporting portion 52 are separately disposed on both sides of the attachment portion 43 (i.e., both sides of the opening 42).

The first supporting portion 51 and the second supporting portion 52 protrude in a direction crossing (e.g., substantially perpendicular to) the bottom wall 11. For example, the first supporting portion 51 and the second supporting portion 52 protrude substantially in parallel to the attachment surface 43a. In this embodiment, the first supporting portion 51 and the second supporting portion 52 protrude in a direction (i.e., the thickness direction of the housing 4) substantially perpendicular to the bottom wall 11. The first supporting portion 51 and the second supporting portion 52 may protrude in a direction which obliquely intersects the bottom wall 11. A component (i.e., a module or a unit) can be engaged with the first supporting portion 51 in a direction crossing (e.g., substantially perpendicular to) the bottom wall 11.

As shown in FIGS. 14 to 16, the housing 4 includes a first fixing portion 53 and a second fixing portion 54. Each of the first fixing portion 53 and the second fixing portion 54 is a protruding portion which protrudes from the inner surface of the housing 4 and is, for example, a boss. A hole 55 is provided in each of the first fixing portion 53 and the second fixing portion 54. The hole 55 is, for example, a screw hole or a screw insertion hole. The hole 55 may be a hole with the bottom or a through hole. The hole 55 is opened in a direction crossing (e.g., substantially perpendicular to) the bottom wall 11.

The first fixing portion 53 is disposed in the vicinity of the first supporting portion 51. The first supporting portion 51 is disposed between the first fixing portion 53 and the attachment portion 43. The second fixing portion 54 is disposed in the vicinity of the second supporting portion 52. The second supporting portion 52 is disposed between the second fixing portion 54 and the attachment portion 43. The first supporting portion 51 may be disposed outside the first fixing portion 53. The second supporting portion 52 may be disposed outside the second fixing portion 54.

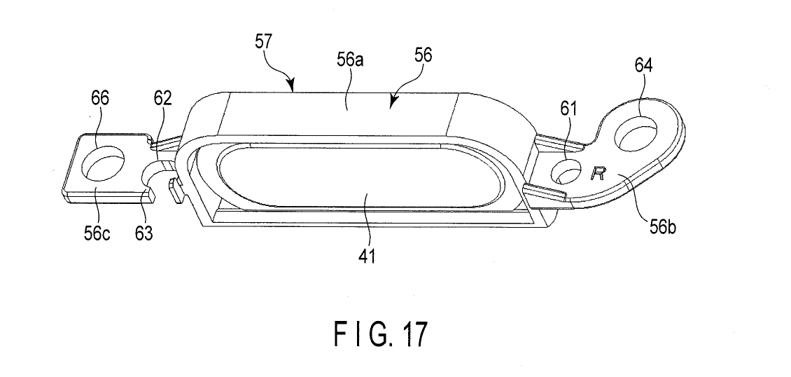

As shown in FIG. 17, a holder 56 (i.e., a speaker holder, a holding portion, a case, or an attachment member) is attached to the speaker 41. The holder 56 and the speaker 41 are integrated into a speaker module 57 (i.e., speaker unit). The housing 4 (e.g., base 15) is an example of a “first member”. The speaker module 57 is an example of a “second member”, a “module”, a “unit”, a “component”, or a “member”.

As shown in FIGS. 14 to 17, the holder 56 includes a first portion 56a, a second portion 56b, and a third portion 56c. The first portion 56a is a holding portion (e.g., supporting portion) that holds the speaker 41. The first portion 56a surrounds the outside of the speaker 41. The first portion 56a faces the sealing portion 50 (i.e., elastic portion).

The first portion 56a includes a first end and a second end opposite to the first end. The second portion 56b is provided at the first end of the first portion 56a and extends in a direction in which it is separated from the speaker 41. The third portion 56c is provided at the second end of the first portion 56a and extends in a direction in which it is separated from the speaker 41. That is, the second portion 56b and the third portion 56c are separately provided on both sides of the first portion 56a.

As shown in FIGS. 14 to 17, the second portion 56b is formed in, for example, a plate shape substantially parallel to the bottom wall 11. The second portion 56b faces the first supporting portion 51 and the first fixing portion 53 in a direction crossing (e.g., substantially perpendicular to) the bottom wall 11. A first engaging portion 61 (i.e., a first attachment portion or a first engaging portion) is provided in the second portion 56b.

The first supporting portion 51 is engaged with the first engaging portion 61. The first engaging portion 61 is, for example, a hole (e.g., a circular hole, a through hole, or an insertion hole) into which the first supporting portion 51 is inserted. The first engaging portion 61 is not limited to the hole, but may be a recess (i.e., depressed portion) provided in the holder 56. The first supporting portion 51 is engaged with (i.e., attached to or inserted into) the first engaging portion 61 in a direction crossing the bottom wall 11. For example, the first supporting portion 51 is engaged with the first engaging portion 61 in a direction substantially parallel to the attachment surface 43a. The first supporting portion 51 is fitted to the first engaging portion 61 to support the speaker module 57.

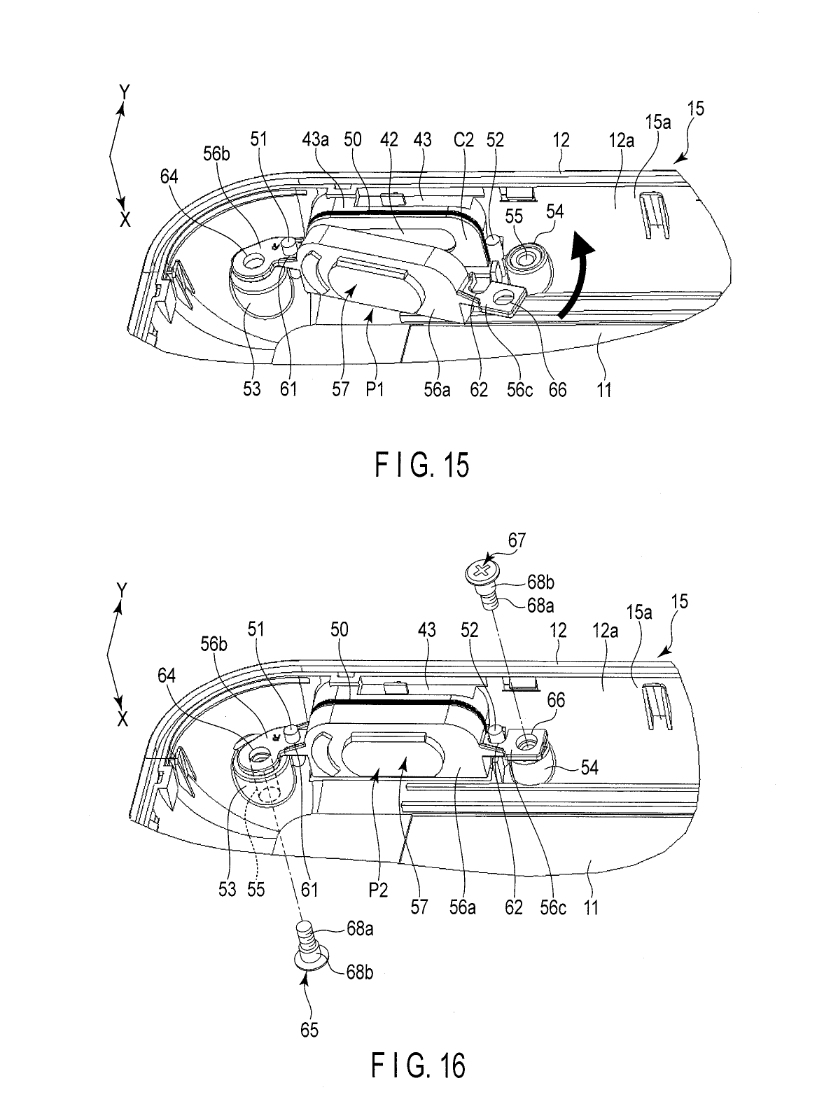

As shown in FIGS. 15 and 16, the speaker module 57 can be pivoted on the first supporting portion 51 (i.e., a center, a rotation center, or a fulcrum) between a first position P1 and a second position P2, with being supported by the first supporting portion 51.

As shown in FIG. 15, the first position P1 (i.e., a temporary fixing position or a temporary mounting position) is away from the side wall 12. At the first position P1, the speaker module 57 is inclined with respect to the side wall 12 in a direction crossing the side wall 12. At the first position P1, the speaker module 57 is away from the sealing portion 50. A gap C2 is provided between the speaker module 57 and the sealing portion 50. At the first position P1, the sealing portion 50 is not compressed.

The speaker module 57 can be moved from the first position P1 to the second position P2 (i.e., main fixing position), while being supported by the first supporting portion 51. In this embodiment, the speaker module 57 is pivoted on the first supporting portion 51, with the first supporting portion 51 engaged with the first engaging portion 61, and is moved from the first position P1 to the second position P2 in the direction substantially parallel to the bottom wall 11.

As shown in FIG. 16, the second position P2 is closer to the side wall 12 (i.e., closer to the opening 42 and the sealing portion 50) than the first position P1. At the second position P2, the speaker module 57 is substantially parallel to the side wall 12. The speaker module 57 is disposed in front of the opening 42 and faces the opening 42.

When the speaker module 57 is moved from the first position P1 to the second position P2, the sealing portion 50 is interposed between the speaker module 57 and the side wall 12. At the second position P2, the speaker module 57 contacts with the sealing portion 50 and presses the sealing portion 50 to the side wall 12. In this way, the sealing portion 50 is compressed (e.g., deformed) between the speaker module 57 and the side wall 12 and liquid-tightly seals a space between the speaker module 57 and the side wall 12. The sealing portion 50 liquid-tightly seals the periphery of the opening 42.

FIGS. 14 to 17, the third portion 56c has, for example, a plate shape which is substantially parallel to the bottom wall 11. The third portion 56c faces the second fixing portion 54 in a direction crossing (e.g., substantially perpendicular to) the bottom wall 11. A second engaging portion 62 (i.e., a second attachment portion or a second engaging portion) is provided in the third portion 56c.

The second engaging portion 62 comes into contact with (e.g., is engaged with) the second supporting portion 52 at the second position P2. In this way, the pivoting of the speaker module 57 is regulated at the second position P2 and the speaker module 57 is positioned at the second position P2. The second supporting portion 52 is an example of a “positioning portion”.

The speaker module 57 (e.g., second portion 56b) has an end facing the second supporting portion 52. The second engaging portion 62 is provided at the end of the speaker module 57. An example of the second engaging portion 62 is a U-shaped cutout which is opened toward the second supporting portion 52. The second supporting portion 52 is engaged with (i.e., inserted into) the second engaging portion 62 in a direction (e.g., a direction substantially parallel to the bottom wall 11) crossing the thickness direction of the housing 4.

For example, the second engaging portion 62 includes a hook 63 (e.g., a claw portion, an engaging portion, or a temporary engaging portion) which is caught in, e.g., the second supporting portion 52. The second engaging portion 62 (e.g., hook 63) is engaged with the second supporting portion 52 at the second position P2 and is temporarily fixed to the second supporting portion 52. In this way, the speaker module 57 is temporarily fixed at the second position P2. In addition, for example, the second engaging portion 62 may include a narrow-width portion (e.g., an engaging portion or a temporary engaging portion) with a width less than the diameter of the second supporting portion 52, instead of the hook 63, and may be temporarily fixed to the second supporting portion 52.

As shown in FIGS. 14 to 17, the second portion 56b of the holder 56 includes a first hole 64 (i.e., a first insertion hole, a first through hole, a first fixing hole, a first hole, or a first attachment hole). The first hole 64 faces the hole 55 of the first fixing portion 53 at the second position P2. A first fixing member 65 (i.e., a first fixing portion, a first attachment member, or a first supporting member) is inserted into the first hole 64 of the holder 56 and the hole 55 of the first fixing portion 53.

The first fixing member 65 is, for example, a screw. The first fixing member 65 is inserted into the first hole 64 and the hole 55 of the first fixing portion 53 in a direction (e.g., a direction substantially perpendicular to) crossing the bottom wall 11. For example, the first fixing member 65 is inserted into the first hole 64 and the hole 55 of the first fixing portion 53 in a direction substantially parallel to the attachment surface 43a.

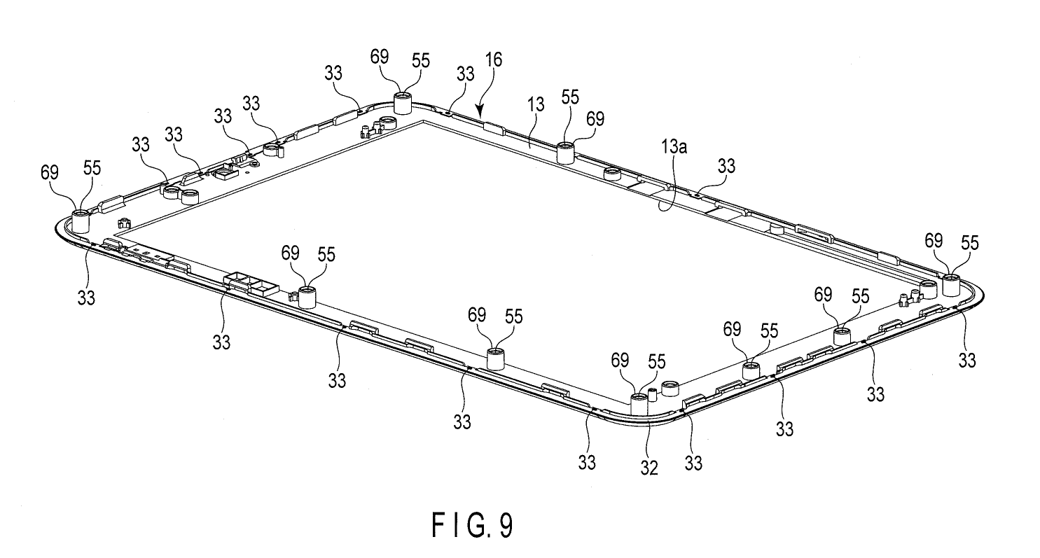

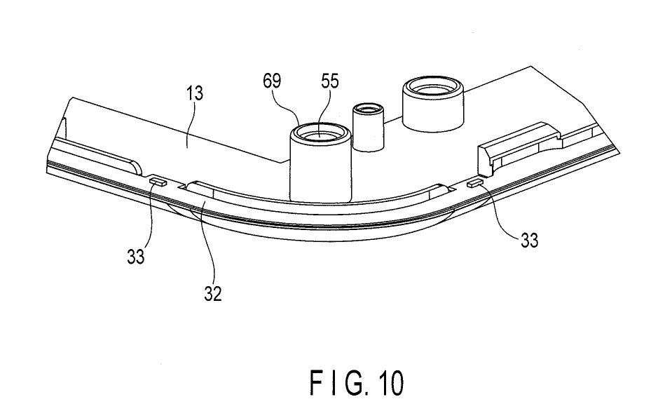

In this embodiment, third fixing portions 69 (see FIGS. 9 and 10) which face the first fixing portions 53 are provided on the inner surface of the mask 16. The third fixing portion 69 includes a screw hole 55. As shown in FIG. 16, for example, the first fixing member 65 is inserted into the hole 55 (e.g., insertion hole) of the first fixing portion 53 and the first hole 64 of the holder 56 from the outside of the housing 4 and is fixed to (e.g., engaged with or inserted into) the screw hole 55 of the third fixing portion 69 of the mask 16. In this way, the speaker module 57 is fixed to the housing 4 at the second position P2.

Instead of the above-mentioned structure, the hole 55 of the first fixing portion 53 may be a screw hole. The first fixing member 65 may be inserted into the first hole 64 of the holder 56 from the inside of the housing 4 and may be fixed to (e.g., engaged with or inserted into) the hole 55 of the first fixing portion 53.

As shown in FIGS. 14 to 17, the third portion 56c of the holder 56 includes a second hole 66 (i.e., a second insertion hole, a second through hole, a second fixing hole, a second hole, or a second attachment hole). The second hole 66 faces the hole 55 of the second fixing portion 54 at the second position P2. A second fixing member 67 (i.e., a second fixing portion, a second attachment member, or a second supporting member) is inserted into the second hole 66 of the holder 56 and the hole 55 of the second fixing portion 54.

The second fixing member 67 is, for example, a screw. The second fixing member 67 is inserted into the second hole 66 and the hole 55 of the second fixing portion 54 in a direction (e.g., a direction substantially perpendicular to) crossing the bottom wall 11. For example, the second fixing member 67 is inserted into the second hole 66 and the hole 55 of the second fixing portion 54 in a direction substantially parallel to the attachment surface 43a.

In this embodiment, the hole 55 of the second fixing portion 54 is a screw hole. The second fixing member 67 is inserted into the second hole 66 of the holder 56 from the inside of the housing 4 and is fixed to (engaged with or inserted into) the hole 55 of the second fixing portion 54. In this way, the speaker module 57 is fixed to the housing 4 at the second position P2.

As shown in FIG. 16, in this embodiment, the first fixing member 65 and the second fixing member 67 are shoulder screws. The shoulder screw includes a screw portion 68a and a non-screw portion 68b (e.g., a body portion or a cylindrical portion). No screw thread is provided in the non-screw portion 68b. Therefore, the non-screw portion 68b has a component tolerance less than the screw portion 68a.

The non-screw portion 68b of the first fixing member 65 is inserted into the first hole 64 of the holder 56. The non-screw portion 68b of the second fixing member 67 is inserted into the second hole 66 of the holder 56. The non-screw portions 68b of the first and second fixing members 65 and 67 are inserted into the holes 64 and 66, respectively, thereby accurately positioning the holder 56. In this way, it is possible to control the amount of compression (e.g., deformation) of the sealing member 17 with high accuracy.

The speaker module 57 is temporarily mounted (e.g., temporarily fixed) at the first position P1 of the housing 4 and is fixed (e.g., mainly fixed) to the housing 4 at the second position P2 moved from the first position P1. Next, an example of a method of attaching the speaker module 57 will be described with reference to FIGS. 15, 16, and 17.

First, before the speaker module 57 is attached, the sealing portion 50 is attached to the side wall 12 (S1 in FIG. 17). The sealing portion 50 may be attached to the speaker module 57, instead of the side wall 12.

Here, a first direction X and a second direction Y are defined from a point of view different from the above. The first direction X intersects the bottom wall 11. In this embodiment, the first direction X is substantially perpendicular to the bottom wall 11. The first direction X may obliquely intersect the bottom wall 11.

As shown in FIG. 15, the speaker module 57 is attached to the first supporting portion 51 in the first direction X (S2 in FIG. 17). The speaker module 57 is attached to the first position P1 away from the side wall 12 such that it does not come into contact with the sealing portion 50 attached to the side wall 12 (such that the sealing portion 50 is not removed). The speaker module 57 is supported by the first supporting portion 51 at the first position P1.

The speaker module 57 is moved from the first position P1 to the second position P2, with being supported by the first supporting portion 51 (S3 in FIG. 17). In this embodiment, the speaker module 57 is pivoted on the first supporting portion 51 in the second direction Y. The second direction Y intersects the first direction X. The second direction Y is a direction in which the speaker module 57 is moved from the first position P1 toward the sealing portion 50 (e.g., toward side wall 12). In this embodiment, the second direction Y is substantially parallel to the bottom wall 11. The second direction Y is a direction crossing (e.g., substantially perpendicular to) the sealing portion 50 (e.g. side wall 12).

While the speaker module 57 is being moved from the first position P1 to the second position P2, the sealing portion 50 is interposed between the speaker module 57 and the side wall 12 and is compressed between the speaker module 57 and the side wall 12 (S4 in FIG. 17). In this way, the circumference of the opening 42 is liquid-tightly sealed.

When the speaker module 57 is moved to the second position P2, the second engaging portion 62 comes into contact with the second supporting portion 52 and the movement of the speaker module 57 is regulated (S5 in FIG. 17). In this way, the speaker module 57 is positioned at the second position P2. In this embodiment, the second engaging portion 62 includes the hook 63 configured to be caught in the second supporting portion 52. Therefore, the speaker module 57 moved to the second position P2 is locked to the second supporting portion 52 at the second position and is held at the second position P2.

Then, the second fixing member 67 is inserted into the second hole 66 of the holder 56 and the hole 55 of the second fixing portion 54 (S6 in FIG. 17). In this way, the speaker module 57 is fixed (mainly fixed) to the housing 4. In this embodiment, after the base 15 and the mask 16 are combined with each other, the first fixing member 65 is inserted into the hole 55 of the first fixing portion 53, the first hole 64 of the holder 56 and is then engaged with the hole 55 of the third fixing portion 69 of the mask 16. In this way, the base 15, the mask 16, and the speaker module 57 are connected to each other.

According to this structure, it is possible to improve the assemblability of the television 1. For example, when the sound emitting opening of the speaker is provided in the same surface as the display screen, the design is restricted by the sound emitting opening and it is difficult to achieve an electronic apparatus with, for example, a narrow frame. Therefore, it is considered that the sound emitting opening is provided in the side wall of the housing and the speaker is attached to the inner surface of the side wall.

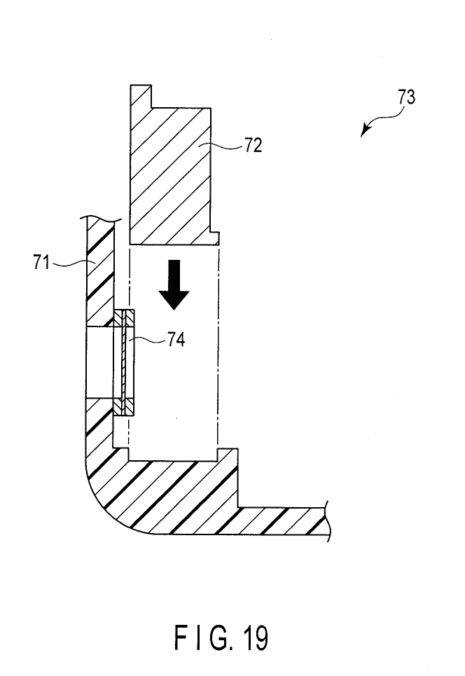

For comparison, FIG. 19 shows an electronic apparatus 73 in which a speaker module 72 is attached in a direction substantially parallel to a side wall 71. The electronic apparatus 73 includes a sealing portion 74 that is compressed between the side wall 71 and the speaker module 72. In this case, when the speaker module 72 is attached in the direction substantially parallel to the side wall 71, the speaker module 72 may be caught in the end of the sealing portion 74 and the sealing portion 74 is likely to be taken off from the side wall 71 or to be obliquely compressed. Therefore, the assemblability of the electronic apparatus 73 having the above-mentioned structure tends to be reduced.

In contrast, in this embodiment, the television 1 includes the housing 4 and the speaker module 57 which is temporarily mounted at the first position P1 of the housing 4 and is fixed to the housing 4 at the second position P2 moved from the first position P1. According to this structure, since attachment is performed in two stages, and it is possible to improve the assemblability of the television 1.

For example, in this embodiment, the television 1 includes the sealing portion 50 which is interposed between the speaker module 57 and the side wall 12 while the speaker module 57 is being moved from the second position P2 to the first position P1. According to this structure, it is easy to press the sealing portion 50 in an appropriate direction and it is possible to prevent, for example, the twist or removal of the sealing portion 50. In this way, it is possible to improve the assemblability of the television 1.

In this embodiment, the speaker module 57 is engaged with the first supporting portion 51 in the first direction X and is moved from the first position P1 to the second position P2 in the second direction Y crossing the first direction X. According to this structure, the direction in which the speaker module 57 presses the sealing portion 50 can be different from the direction in which the speaker module 57 is attached to the housing 4. Therefore, for example, it is possible to attach the speaker module 57 to the first supporting portion 51 in the direction crossing the bottom wall 11. As a result, it is possible to improve the assemblability of the television 1.

In this embodiment, the speaker module 57 is moved to the second position P2 and is then attached to the housing 4, and the fixing members 65 and 67 are provided to fix the speaker module 57 at the second position P2. According to this structure, it is possible to firmly fix the speaker module 57 at the second position P2.

In this embodiment, the fixing member 67 is attached to the housing 4 in the direction crossing the bottom wall 11. According to this structure, for example, it is possible to attach the fixing member 67 to the housing 4 in the direction crossing the bottom wall 11. Therefore, it is possible to further improve the assemblability of the television 1.

In this embodiment, the first supporting portion 51 is the first protrusion which protrudes in the direction crossing the bottom wall 11. The speaker module 57 includes the first engaging portion 61 to which the first protrusion is fitted, is pivoted on the first protrusion, which the first engaging portion 61 is engaged with the first protrusion, and is moved from the first position P1 to the second position P2 in the direction substantially parallel to the bottom wall 11. According to this structure, it is possible to stably move the speaker module 57 in the direction substantially parallel to the bottom wall 11. Therefore, it is possible to further improve the assemblability of the television 1.

In this embodiment, the housing 4 includes the positioning portion (e.g., the second supporting portion 52). The speaker module 57 includes the second engaging portion 62 which is engaged with the positioning portion at the second position P2 and is temporarily fixed. According to this structure, it is possible to accurately position the speaker module 57 at the second position. Therefore, it is possible to further improve the assemblability of the television 1.

In this embodiment, the positioning portion is the second protrusion which protrudes in the direction crossing the bottom wall 11. The second engaging portion 62 is a cutout which is provided at the end of the speaker module 57 facing the second protrusion and is opened toward the second protrusion. According to this structure, it is easy for the speaker module 57 rotated to the second position P2 to be engaged with the positioning portion. Therefore, it is possible to further improve the assemblability of the television 1.

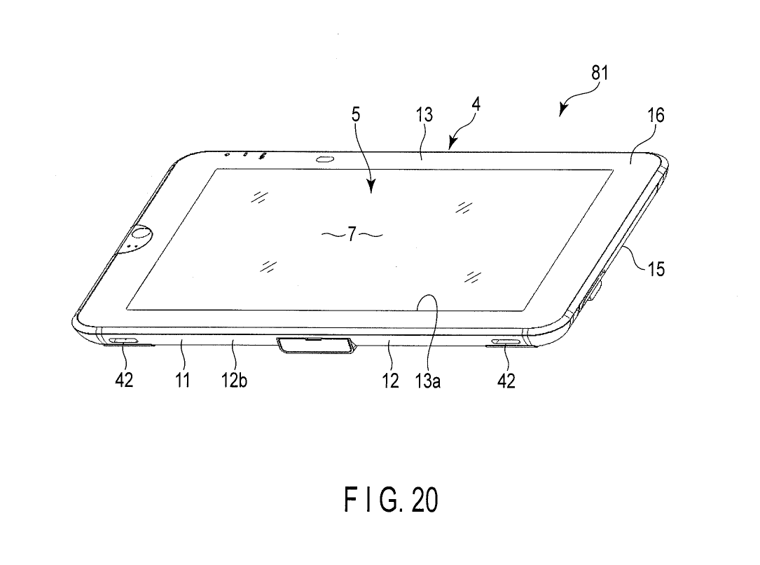

This embodiment can also be applied to, for example, an electronic apparatus 81 shown in FIG. 20. The electronic apparatus 81 is, for example, a slate PC. As described above, this embodiment and the following embodiments can be widely applied to various electronic apparatuses.

In this embodiment, the attachment structure of the speaker has been described. The component to which the attachment structure according to this embodiment can be applied is not limited to the speaker. The attachment structure can be widely applied to various components, such as a connector, a camera, a switch, an LED, a microphone, and a receiver.

In this embodiment, a component is attached to the side wall 12. However, the attachment structure according to this embodiment is not limited thereto. The attachment structure can also be applied to a case in which a component is attached to the bottom wall 11, the upper wall 13, or other portions. The moving direction of the component from the first position P1 to the second position P2 is not limited to the direction substantially parallel to the bottom wall 11. The movement of the component from the first position P1 to the second position P2 is not limited to rotation, but it may be sliding or other movements. The second supporting portion 52 may not be provided.

### Second Embodiment

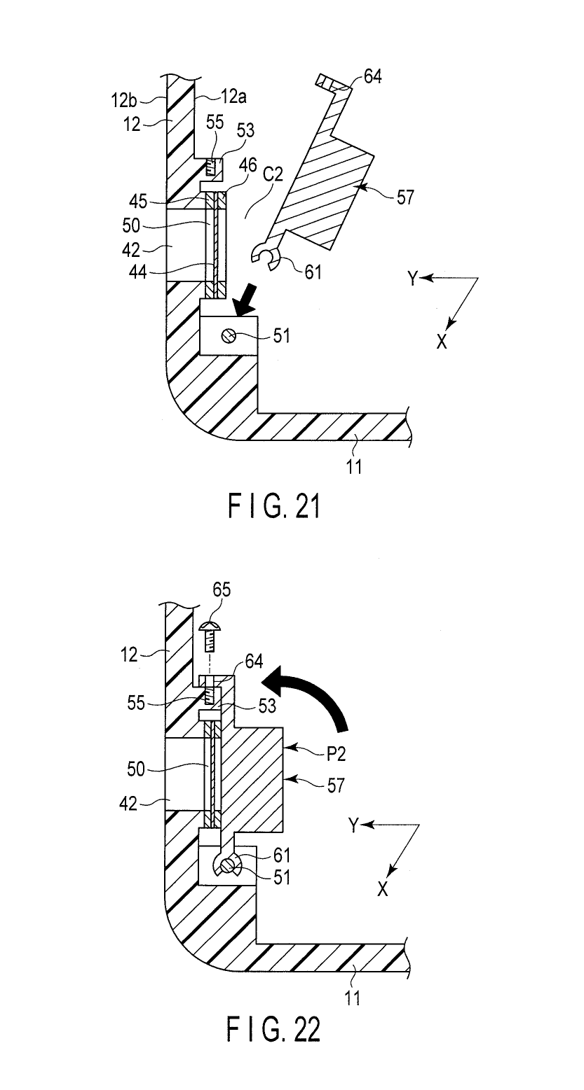

Next, a television 1 according to a second embodiment will be described with reference to FIGS. 21 and 22. In the second embodiment, components having the same or similar functions as those in the first embodiment are denoted by the same reference numerals and the description thereof will not be repeated. Structures other than the following structures are the same as those in the first embodiment.

As shown in FIG. 21, a supporting portion 51 and a fixing portion 53 are provided in a housing 4. The supporting portion 51 is, for example, a cylindrical pin which protrudes substantially in parallel to the bottom wall 11. A speaker module 57 includes a engaging portion 61 and a hole 64. The speaker module 57 is attached to the supporting portion 51 in a first direction X which intersects the bottom wall 11. The speaker module 57 is supported by the supporting portion 51 at a first position P1 which is away from a side wall 12.

As shown in FIG. 22, the speaker module 57 is moved from the first position P1 to a second position P2, with the engaging portion 61 supported by the supporting portion 51. In this embodiment, the speaker module 57 is pivoted on the supporting portion 51, with the engaging portion 61 supported by the supporting portion 51, and is moved from the first position P1 to the second position P2. The speaker module 57 is moved from the first position P1 to the second position P2 in a second direction Y crossing the first direction X.

While the speaker module 57 is being moved from the first position P1 to the second position, a sealing portion 50 is interposed and compressed between the speaker module 57 and the side wall 12. The fixing member 65 fixes the speaker module 57 at the second position P2. The fixing member 65 is attached to the housing 4 in a direction (e.g., a direction substantially parallel to the side wall 12) crossing the bottom wall 11.

According to this structure, similarly to the first embodiment, it is possible to improve the assemblability of the television 1.

### Third Embodiment

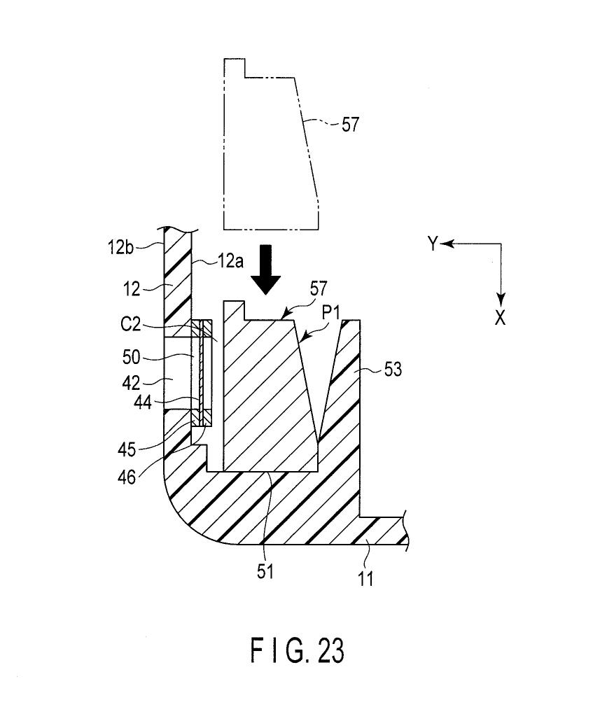

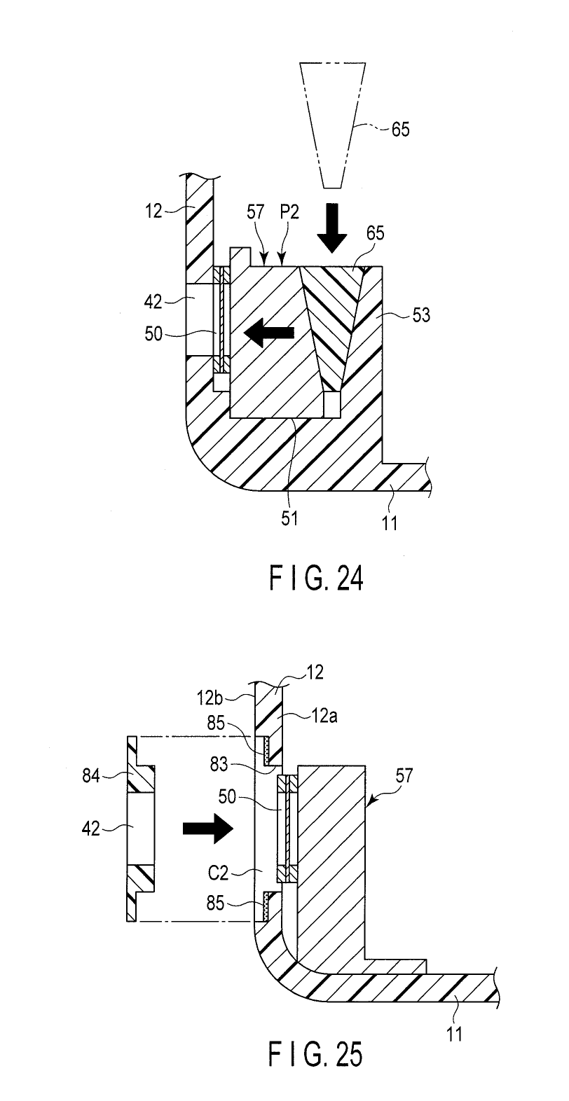

Next, a television 1 according to a third embodiment will be described with reference to FIGS. 23 and 24. In the third embodiment, components having the same or similar functions as those in the first embodiment are denoted by the same reference numerals and the description thereof will not be repeated. Structures other than the following structures are the same as those in the first embodiment.

As shown in FIG. 23, a housing 4 includes a supporting portion 51. In this embodiment, the supporting portion 51 is a mounting surface (e.g., an attachment surface, a temporary mounting surface, a sliding surface, or a guide) which is provided in the housing 4. A speaker module 57 is placed on the mounting surface and is supported by the supporting portion 51. The speaker module 57 is placed on the supporting portion 51 in a first direction X crossing a bottom wall 11. The speaker module 57 is supported by the supporting portion 51 at a first position P1 which is away from a side wall 12.

As shown in FIG. 24, the speaker module 57 is moved from the first position P1 to the second position P2, with being supported by the supporting portion 51. In this embodiment, the speaker module 57 slides from the first position P1 to the second position P2 (i.e., toward the side wall 12), with being placed on the supporting portion 51.

In this embodiment, for example, a fixing member 65 is attached to the rear side of the speaker module 57. The fixing member 65 is attached to the housing 4 in a direction (e.g., a direction substantially parallel to the side wall 12) crossing the bottom wall 11. The fixing member 65 has, for example, a wedge shape. When the fixing member 65 is attached, the speaker module 57 is pressed to the side wall 12 and is moved to the second position P2. The fixing member 65 fixes the speaker module 57 at the second position P2.

According to this structure, similarly to the first embodiment, it is possible to improve the assemblability of the television 1.

### Fourth Embodiment

Next, a television 1 according to a fourth embodiment will be described with reference to FIG. 25. In the fourth embodiment, components having the same or similar functions as those in the first embodiment are denoted by the same reference numerals and the description thereof will not be repeated. Structures other than the following structures are the same as those in the first embodiment.

As shown in FIG. 25, a first opening 83 and a cover 84 are provided in a side wall 12. The cover 84 is removably attached to the side wall 12 and covers the first opening 83. The cover 84 is attached to the side wall 12 by, for example, a waterproof double-sided tape 85. A second opening 42 (e.g., a sound emitting portion or a sound emitting opening) is provided in the cover 84. The cover 84 is a portion of the side wall 12.

A sealing portion 50 is attached to a speaker module 57. The speaker module 57 is attached to the inside of the housing 4. The cover 84 is attached to the side wall 12 after the speaker module 57 is attached. When the cover 84 is attached to the side wall 12, the sealing portion 50 is interposed and compressed between the cover 84 and the speaker module 57.

According to this structure, it is possible to prevent the sealing portion 50 from being removed or inclined. In this way, it is possible to improve the assemblability of the television 1.

### Fifth Embodiment

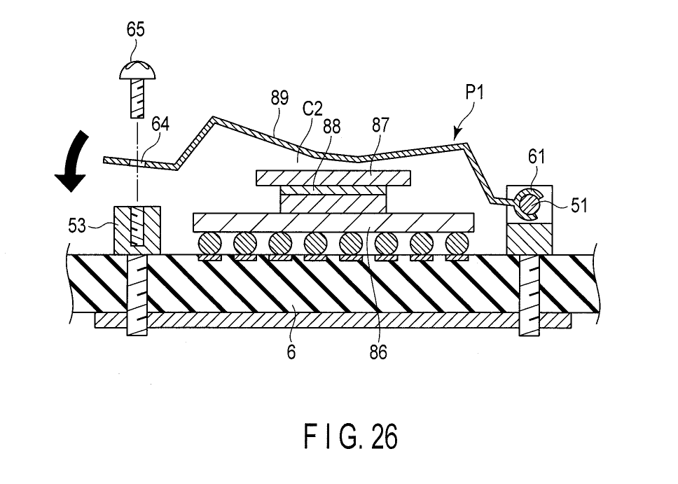

Next, a television 1 according to a fifth embodiment will be described with reference to FIG. 26. In the fourth embodiment, components having the same or similar functions as those in the first embodiment are denoted by the same reference numerals and the description thereof will not be repeated. Structures other than the following structures are the same as those in the first embodiment.

In the first to fourth embodiments, the component attachment structures for waterproofing have been described. The purpose of the attachment structure is not limited to waterproofing, but the attachment structure can be widely applied for various purposes. In this embodiment, the attachment structure is applied to, for example, a component for pressing a heat-generating component.

As shown in FIG. 26, a circuit board 6 includes a heat-generating component 86. The heat-generating component 86 is, for example, a CPU or a graphic chip, but is not limited thereto. A heat-receiving member 87 (or a heat-dissipating member 87) is attached to the heat-generating component 86. A thermally conductive member 88 (i.e., heat transfer member) is interposed between the heat-generating component 86 and the heat-receiving member 87. The thermally conductive member 88 is, for example, a thermally conductive sheet or thermally conductive grease. The thermally conductive member 88 is an example of an elastic portion.

The television 1 includes a pressing member 89 (i.e., a pressing portion or a pressing component). The heat-receiving member 87 is disposed between the heat-generating component 86 and the pressing member 89. The pressing member 89 presses the heat-receiving member 87 toward the heat-generating component 86. The thermally conductive member 88 is interposed between the heat-receiving member 87 and the heat-generating component 86. In this way, the thermal connection between the heat-generating component 86 and the heat-receiving member 87 is strengthened.

As shown in FIG. 26, the circuit board 6 includes a supporting portion 51 and a fixing portion 53. The supporting portion 51 is, for example, a cylindrical pin which protrudes substantially in parallel to the circuit board 6. The fixing portion 53 is, for example, a stud provided on the circuit board 6. The pressing member 89 includes a engaging portion 61 and a hole 64.

The pressing member 89 is supported by the supporting portion 51 at the first position P1 which is away from the heat-receiving member 87. The pressing member 89 is moved from the first position P1 toward the second position P2 close to the heat-receiving member 87, with the engaging portion 61 supported by the supporting portion 51. In this embodiment, the pressing member 89 is pivoted on the supporting portion 51, with the engaging portion 61 supported by the supporting portion 51, and is moved from the first position P1 to the second position P2.

While the pressing member 89 is being moved from the first position P1 to the second position, the thermally conductive member 88 is interposed and compressed between the heat-receiving member 87 and the heat-generating component 86 (i.e., between the pressing member 89 and the heat-generating component 86). The fixing member 65 fixes the pressing member 89 at the second position P2.

According to this structure, similarly to the first embodiment, it is possible to improve the assemblability of the television 1. In addition, according to this embodiment, it is possible to reduce the number of fixing members, such as screws. This contributes to reducing the manufacturing costs of the television 1.

In the first to fifth embodiments, the sealing portion 50 or the thermally conductive member 88 is interposed between the components of the attachment structure, but the embodiments are not limited thereto. For example, the embodiments can be applied to a structure in which a conductive member for suppressing electromagnetic interference (EMI) is interposed between a connector and a conductor portion of the housing 4.

### Sixth Embodiment

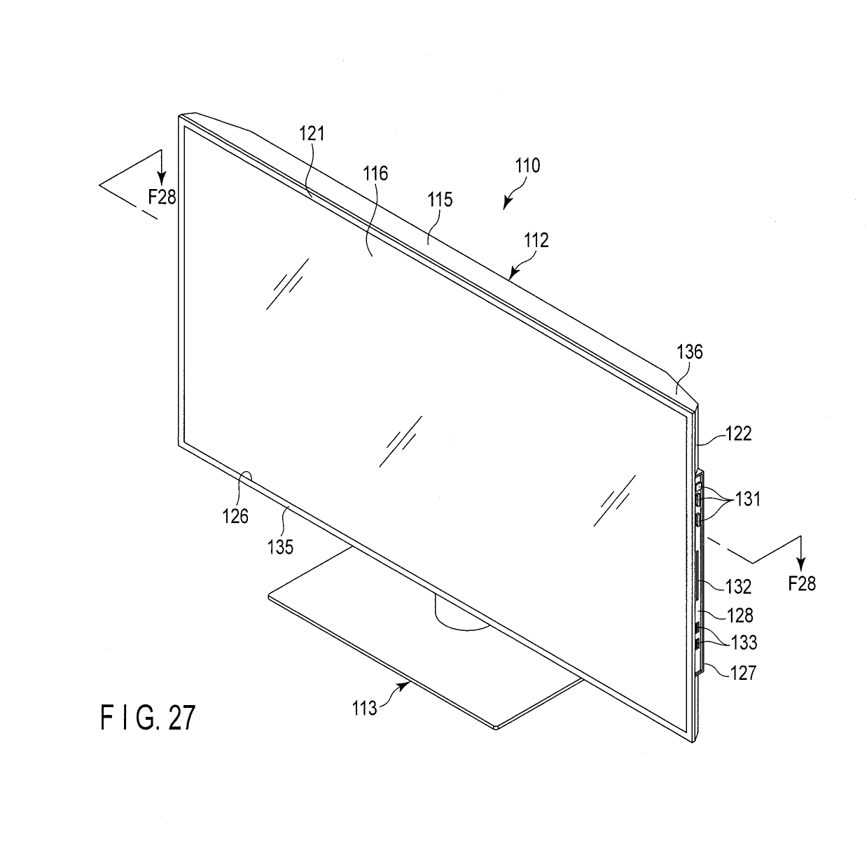

FIG. 27 shows a television 110 according to a sixth embodiment. The television 110 is an example of an electronic apparatus. The television 110 includes a display unit 112 and a stand 113. The display unit 112 includes a housing 115 and a display device 116 which is accommodated in the housing 115.

The housing 115 includes a front surface 121 and a side surface 122 (i.e., an outer surface, a surface, a side wall, a wall portion, or a wall). An opening 126 is provided in the front surface 121. A display surface of the display device 116 on which an image is displayed is exposed through the opening 126.

The side surface 122 extends in a direction crossing the front surface 121. A portion of the side surface 122 is inclined toward the center of the housing 115 in a direction from the front surface 121 to the rear side. An interface unit 127 is provided on the side surface 122. The interface unit 127 protrudes from the side surface 122. The interface unit 127 includes a side wall 128 (i.e., an outer surface, a surface, a wall portion, or a wall) which extends in a direction crossing (e.g., substantially perpendicular to) the front surface 121. The side wall 128 is an example of a wall portion.

A plurality of buttons 131 (e.g., switches, components, members, or input units), a card opening 132 (i.e., a first opening), and a plurality of terminal openings 133 (i.e., second openings) are provided in the side wall 128. The plurality of buttons 131 include, for example, a power button, a channel switching button, and a volume adjusting button. The button 131 is an example of an operation unit (i.e., a component or a member). A card, such as a B-CAS card, is inserted into the card opening 132. For example, a USB terminal or an HDMI terminal is inserted into the terminal opening 133.

The housing 115 further includes a rear surface opposite to the front surface 121 and a lower surface which extends in a direction crossing the front surface 121. For example, a plurality of vent holes are provided in the rear surface and the stand 113 is fixed to the rear surface. An opening for a speaker is provided in the lower surface.

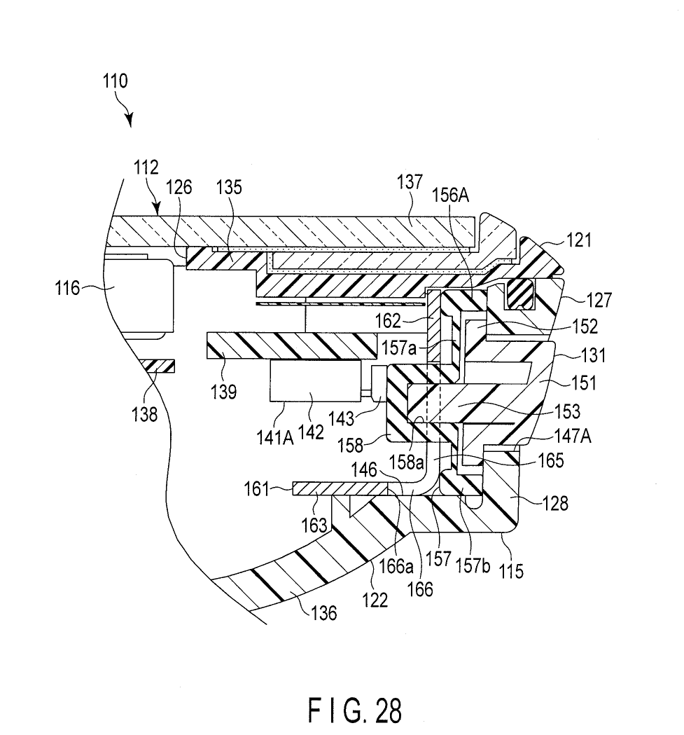

As shown in FIG. 28, the housing 115 includes a front cover 135 and a rear cover 136. The front cover 135 includes the front surface 121 of the housing 115. The rear cover 136 includes the side surface 122, the rear surface, and the lower surface of the housing 115.

A translucent panel 137 is attached to the front surface 121 of the housing 115. The panel 137 covers the opening 126. The display device 116 is exposed to the outside over the panel 137.

A main board 138 (i.e., a first board or a first circuit board) and a module board 139 (i.e., a circuit board, a wiring board, a component, a unit, a second board, or a second circuit board) are provided in the housing 115. The main board 138 is, for example, a rectangular printed wiring board. The main board 138 includes a plurality of electronic components. For example, the main board 138 is attached to the display device 116 with spacers interposed therebetween.

The module board 139 is, for example, a printed wiring board. The module board 139 extends in a direction crossing (e.g., a direction substantially perpendicular to) the side wall 128. The module board 139 is substantially parallel to the front surface 121 and faces the front surface 121. The size of the module board 139 is less than that of the main board 138. The module board 139 is closer to the side wall 128 than the main board 138. The module board 139 is electrically connected to the main board 138 by, for example, a cable.

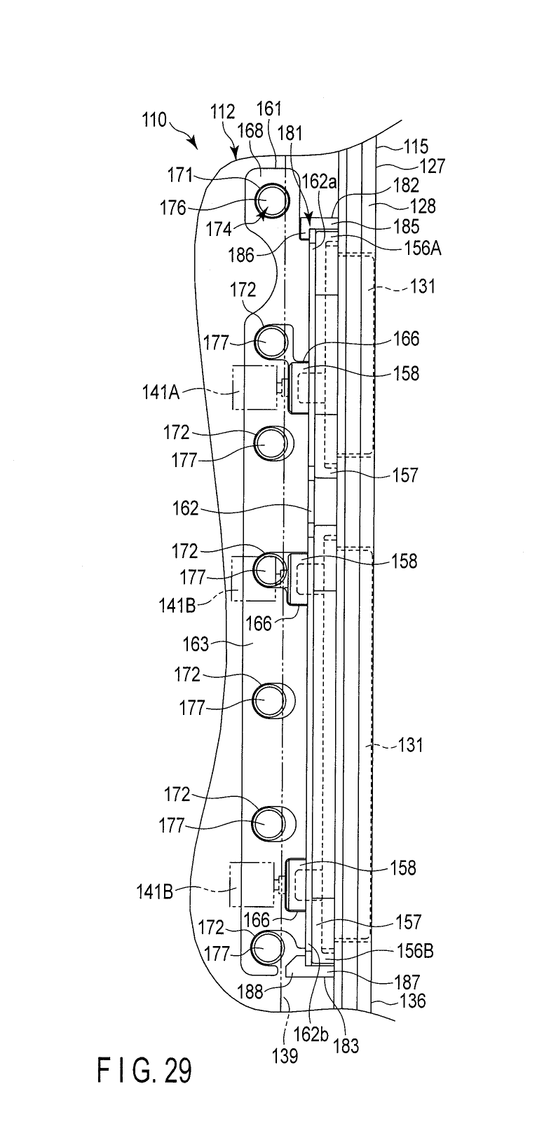

FIG. 29 shows the circumference of the side wall 128. As represented by a two-dot chain line in FIG. 29, for example, a plurality of switches 141A and 141B (i.e., components, modules, or units), a card slot, and a plurality of connectors are mounted on the module board 139. The switch 141A is an example of an electronic component. Two switches 141B are an example of another electronic component.

The card slot is exposed to the outside through the card opening 132. A card, such as a B-CAS card, is inserted into the card slot. The connector is exposed to the outside through the terminal opening 133. For example, a USB terminal or an HDMI terminal is inserted into the connector.

The plurality of switches 141A and 141B are disposed so as to correspond to a plurality of buttons 131. As shown in FIG. 28, each of the switches 141A and 141B includes a component body 142 (i.e., a first portion, a fixing portion, a housing, a case, or a fixed portion) and a pressing portion 143 (i.e., a second portion, a moving portion, a movable portion, an end, an operated unit, a pressure-sensitive portion, or a portion). The component body 142 is fixed to the module board 139 by, for example, soldering. An opening which faces the side wall 128 is provided in the component body 142.

The pressing portion 143 protrudes from the opening of the component body 142 to the side wall 128. When an external pressing force is applied to the pressing portion 143, the pressing portion 143 is elastically moved into the component body 142. When a part of the pressing portion 143 is inserted into the component body 142, the switches 141A and 141B operate. In other words, the switches 141A and 141B are operated by force applied to the pressing portion 143. When the pressing force applied to the pressing portion 143 is released, the pressing portion 143 elastically returns to a predetermined position.

The interface unit 127 includes the side wall 128 and a bottom wall 136 (i.e., a wall portion, a wall, a lower surface, a fixing surface, or an attachment surface) which extends in a direction crossing (e.g., substantially perpendicular to) the side wall 128. The bottom wall 136 is an example of a “first wall”. The bottom wall 146 faces the front cover 135. The bottom wall 146 faces at least a portion of the module board 139.

The side wall 128 is an example of a “second wall”. A plurality of openings 147A and 147B (i.e., openings, holes, insertion portions, or exposed portions) are provided in the side wall 128. The opening 147B is an example of another opening. The shapes of the openings 147A and 147B correspond to the shapes of the plurality of buttons 131. For example, the opening 147A corresponding to the power button 131 has a substantially square shape. The opening 147B corresponding to the channel switching button 131 or the volume adjusting button 131 has a substantially rectangular shape. The corresponding buttons 131 are inserted into the openings 147A and 147B and are exposed to the outside of the housing 115.

The button 131 includes an exposed portion 151 (i.e., an operation portion, an insertion portion, a first portion, or a portion), a flange portion 152 (i.e., a engaging portion, a locking portion, or a second portion), and a protruding portion 153 (i.e., a pressing portion, a projecting portion, a engaging portion, an operation portion, a third portion, or a portion). The exposed portion 151 is inserted into the corresponding opening 147A or 147B and is exposed to the outside of the housing 115.

The flange portion 152 is provided at the end of the exposed portion 151 which is disposed in the housing 115. The flange portion 152 faces the side wall 128 from the inside of the housing 115. The flange portion 152 is locked to the side wall 128 from the inside of the housing 115. The protruding portion 153 protrudes from the exposed portion 151 to the inside of the housing 115. The leading end of the protruding portion 153 faces the pressing portion 143 of the corresponding switch 141A or 141B. The leading end of the protruding portion 153 is further away from the side wall 128 from the flange portion 152.

In the housing, a plurality of key pads 156A and 156B (i.e., packing portions, sealing portions, blocking members, interposed members, elastic portions, waterproof members, or members) are arranged so as to correspond to the plurality of buttons 131. The key pads 156A and 156B are made of, for example, silicon with elasticity. The material forming the key pads 156A and 156B is not limited to silicon, but the key pads 156A and 156B may be made of elastoner or other synthetic rubber materials. Each of the key pads 156A and 156B includes a contact portion 157 (i.e., a fixing portion, an interposed portion, a packing portion, a sealing portion, or a first portion) and a displacement portion 158 (i.e., a movable portion or a second portion). The contact portion 157 and the displacement portion 158 are integrated with each other.

The contact portion 157 surrounds the edge of the flange portion 152 of the button 131 and covers the end of the exposed portion 151 at which the flange portion 152 is provided. The contact portion 157 comes into liquid-tight (e.g., watertight) contact with the side wall 128 around the corresponding opening 147A or 147B. The contact portion 157 is not limited thereto, but it may come into contact with the side wall 128 at a level less than the liquid-tight contact level. The contact portion 157 covers the opening 147A or 147B into which the button 131 is inserted. In this way, as shown in FIG. 29, the key pad 156A closes the opening 147A. The key pad 156B closes the opening 147B. The contact portion 157 may integrally cover a plurality of openings 147A and 147B.

As shown in FIG. 28, a part 157a of the contact portion 157 which covers the end of the exposed portion 151 is thinner than another part 157b of the contact portion 157 which surrounds the edge of the flange portion 152. The part 157a that covers the end of the exposed portion 151 is more likely to be deformed than the part 157b which surrounds the edge of the flange portion 152.

The displacement portion 158 is surrounded by the part 157a of the contact portion 157. The displacement portion 158 protrudes from the part 157a of the contact portion 157 to the inside of the housing 115. A recess 158a is provided in the displacement portion 158 so as to face the button 131. A part of the protruding portion 153 of the button 131 is inserted into the recess 158a. The protruding portion 153 of the button 131 may come into contact with the side surface of the recess 158a and may be inserted into the recess 158a. Alternatively, the protruding portion 153 may be inserted into the recess 158a with a gap between the protruding portion 153 and the side surface of the recess 158a.

The displacement portion 158 is thicker than the part 157a of the contact portion 157. When the displacement portion 158 is pressed by the protruding portion 153 of the button 131, it is elastically displaced (i.e., moved). That is, when the displacement portion 158 is pressed by the protruding portion 153, the part 157a of the contact portion 157 which surrounds the displacement portion 158 is elastically deformed. In this way, the displacement portion 158 is displaced in a direction in which it is pressed by the protruding portion 153. The displacement portion 158 is a displaceable (i.e., movable) portion.

The displacement portion 158 is disposed between the protruding portion 153 of the button 131 and the pressing portion 143 of the corresponding switch 141A or 141B. The protruding portion 153 of the button 131 comes into contact with (i.e., faces) the displacement portion 158. Therefore, when the button 131 is pressed by, for example, the user, the protruding portion 153 displaces the displacement portion 158 and the displacement portion 158 presses the pressing portion 143. When the button 131 is pressed, the switch 141A or 141B is operated by the pressing force from the displaced displacement portion 158.

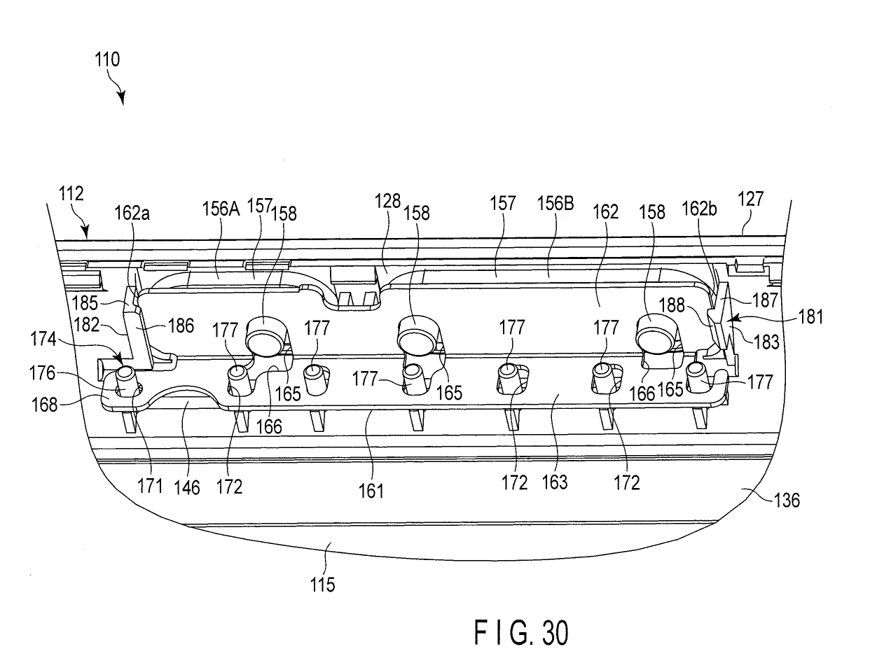

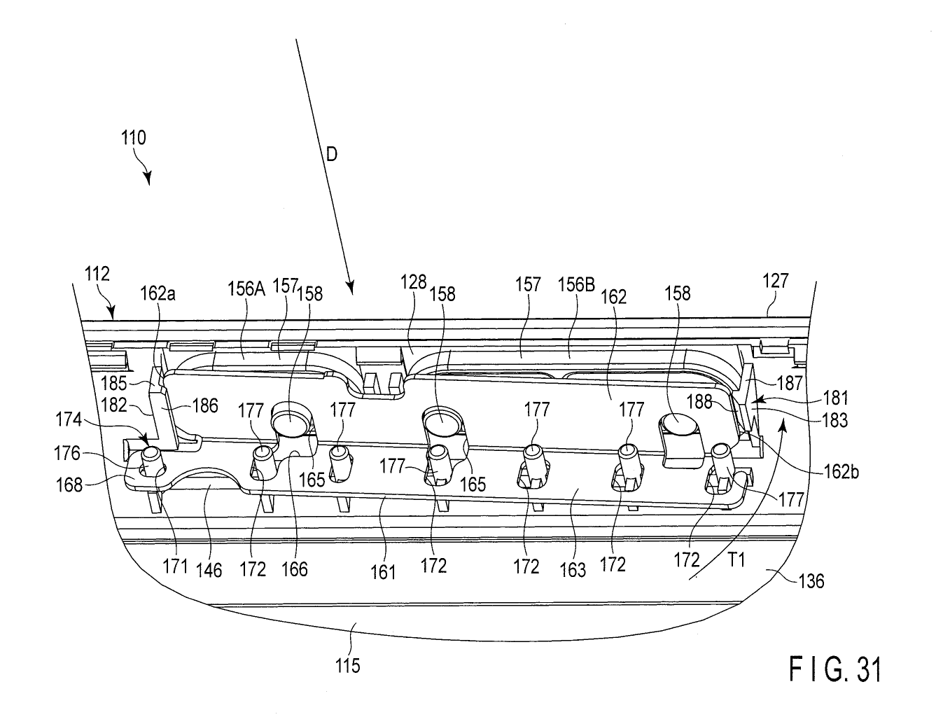

FIG. 30 shows the circumference of the side wall 128 from the inside of the housing 115. As shown in FIG. 30, a supporting member 161 (i.e., a supporting portion, a contact portion, a pressing portion, a component, a member, a portion, a module, or a unit) is provided in the housing 115. In this embodiment, the housing 115 (or a portion of the housing 115) is an example of a “first member”. The supporting member 161 is an example of a “second member”.

The supporting member 161 is, for example, a metal plate which is bent in an L-shape. The supporting member 161 includes a rectangular pressing portion 162 (i.e., a supporting portion, a contact portion, a wall portion, a first portion, or a portion) and a rectangular attachment portion 163 (i.e., a fixing portion, a second portion, or a portion).

As shown in FIG. 28, at least a part of the pressing portion 162 is disposed between the side wall 128 and the module board 139 and faces the side wall 128. The pressing portion 162 comes into contact with (i.e., faces) the plurality of key pads 156A and 156B and comes into contact with the part 157b of the contact portion 157. Therefore, as shown in FIG. 29, the contact portions 157 of the key pads 156A and 156B are interposed between the side wall 128 and the pressing portion 162. In other words, the pressing portion 162 is closer to the module board 139 than the contact portions 157 of the key pads 156A and 156B.

As shown in FIG. 28, a plurality of insertion holes 165 (i.e., openings, openings, holes, cutouts, or concave portions) into which the displacement portions 158 of the plurality of key pads 156A and 156B are inserted are provided in the pressing portion 162. The insertion hole 165 is an example of an insertion portion. As shown in FIG. 30, the plurality of insertion holes 165 are arranged in the longitudinal direction of the pressing portion 162. The insertion hole 165 extends from a portion corresponding to the displacement portion 158 to the attachment portion 163. The displacement portion 158 can be displaced in the insertion hole 165.

The attachment portion 163 extends in a direction (i.e., a direction substantially perpendicular to) crossing the pressing portion 162. The attachment portion 163 extends in a direction in which it is separated from the side wall 128. The attachment portion 163 comes into contact with the bottom wall 146. A plurality of cutouts 166 are provided in the attachment portion 163. Each of the cutouts 166 is connected to the insertion hole 165. As shown in FIG. 28, the edge 166a of the cutout 166 facing the side wall 128 is further away from the side wall 128 than the leading end of the displacement portion 158 of the key pad 156.

As shown in FIG. 30, an extension portion 168 (i.e., a fixing portion or a engaging portion) extends from the attachment portion 163. The extension portion 168 extends in the longitudinal direction of the attachment portion 163 from one end of the attachment portion 163 in the longitudinal direction. For example, a circular shaft hole 171 (i.e., a fitting hole, an opening, an opening, a hole, a circular hole, or a concave portion) is provided in the extension portion 168. The shaft hole 171 is an example of a “engaging portion”. As shown in FIG. 29, an end 162a of the pressing portion 162 is disposed on the side of the extension portion 168. The shaft hole 171 is further away from the center of the attachment portion 163 than the end 162a of the pressing portion 162.

A plurality of fixing holes 172 (i.e., attachment portions, holes, through holes, openings, or fixing portions) are provided in the attachment portion 163. The plurality of fixing holes 172 are arranged in the longitudinal direction of the attachment portion 163. The fixing hole 172 is, for example, a long hole which extends to the pressing portion 162. As shown in FIG. 30, the fixing hole 172 may be connected to the cutout 166, or it may be cut out. The fixing hole 172 closest to the extension portion 168 is a long hole shorter than the fixing hole 172 which is furthest from the extension portion 168.

A supporting portion 174 (i.e., an engaging portion, a hooking portion, a temporary engaging portion, or a guide portion) is provided on the bottom wall 146. The supporting portion 174 includes a plurality of protruding portions 176 and 177 (i.e., protrusions, supporting protrusions, supporting portions, pins, convex portions, or insertion portions). Each of the protruding portions 176 and 177 protrudes from the bottom wall 146. One protruding portion 176 is inserted into the shaft hole 171. A plurality of protruding portions 177 are inserted into a plurality of fixing holes 172. In other words, the protruding portions 176 and 177 are inserted (e.g., fitted) into the shaft hole 171 and the fixing holes 172.

The protruding portions 176 and 177 inserted into the shaft hole 171 and the fixing holes 172 are welded to the attachment portion 163. That is, the leading ends of the protruding portions 176 and 177 are heated and deformed to face the attachment portion 163 from the side opposite to the bottom wall 146. In this way, the attachment portion 163 is fixed to the bottom wall 146. The fixation of the attachment portion 163 is not limited thereto. For example, the attachment portion 163 may be fixed to the bottom wall 146 by screws.

As shown in FIG. 30, a fixing portion 181 (i.e., an attachment portion, a pressing portion, or a portion) is provided on the side wall 128. The fixing portion 181 includes a first engaging portion 182 (i.e., a first fixing portion, a first engaging portion, a first supporting portion, or a first holding portion) and a second engaging portion 183 (i.e., a second fixing portion, a second engaging portion, a second supporting portion, or a second holding portion). The first and second engaging portions 182 and 183 are an example of a pair of engaging portions.

As shown in FIG. 29, the first engaging portion 182 includes a base portion 185 (i.e., first portion) and a claw portion 186 (i.e., a second portion, an engaging portion, a engaging portion, a hook, a pressing portion, or a supporting portion). The base portion 185 protrudes from the side wall 128 to the inside of the housing 115. The base portion 185 comes into contact with one end 162a of the pressing portion 162. The claw portion 186 extends from the leading end of the base portion 185 to the second engaging portion 183 along the side wall 128. The contact portion 157 of the key pad 156A and the pressing portion 162 of the supporting member 161 are interposed between the side wall 128 and the claw portion 186. In this way, the contact portion 157 of the key pad 156A is deformed (i.e., compressed and deformed) between the side wall 128 and the pressing portion 162′.

The second engaging portion 178 includes a base portion 187 and a claw portion 188. The base portion 187 protrudes from the side wall 128 to the inside of the housing 115. The base portion 187 comes into contact with the other end 162b of the pressing portion 162. The base portion 187 is formed so as to be elastically deformed. The claw portion 188 extends from the leading end of the base portion 187 to the first engaging portion 182 along the side wall 128. The contact portion 157 of the key pad 156B and the pressing portion 162 of the supporting member 161 are interposed between the side wall 128 and the claw portion 188. In this way, the contact portion 157 of the key pad 156B is deformed (e.g., compressed) between the side wall 128 and the pressing portion 162.

The pressing portion 162 is interposed between the first and second engaging portions 182 and 183. The contact portions 157 of the key pads 156A and 156B and the pressing portion 162 of the supporting member 161 are interposed between the side wall 128 and the claw portions 186 and 188, respectively. In this way, the fixing portion 181 fixes the supporting member 161 and the pressing portion 162 presses the contact portion 157 of the key pad 156A or 156B to the side wall 128.

Next, an example of a method of attaching the supporting member 161 will be described with reference to FIG. 31. The method of attaching the supporting member 161 is not limited to the following method.

First, the corresponding key pads 156A and 156B are attached to the buttons 131. That is, the protruding portion 153 of the button 131 is inserted into the recess 158a of the displacement portion 158 and the edge of the flange portion 152 is surrounded by the part 157b of the contact portion 157.

Then, the buttons 131 are attached to the openings 147A and 147B from the inside of the housing 115. When the exposed portions 151 of the buttons 131 are inserted into the openings 147A and 147B, the flange portions 152 come into contact with the side wall 128. The contact portions 157 of the key pads 156A and 156B are attached to the buttons 131 come into contact with the inner surface of the side wall 128.

The contact portion 157 of the key pad 156A is disposed between the side wall 128 and the claw portion 186 of the first engaging portion 182. The contact portion 157 of the key pad 156B is disposed between the side wall 128 and the claw portion 188 of the second engaging portion 183. In this way, the key pads 156A and 156B are temporarily fixed by the claw portions 186 and 188.

Then, the supporting member 161 is attached to the housing 115. As represented by an arrow D in FIG. 31, the supporting member 161 is moved in a direction (e.g., a direction substantially perpendicular to) crossing the bottom wall 146. In other words, the supporting member 161 approaches the bottom wall 146 in a direction in which the rear cover 136 is opened. In this way, the protruding portions 176 and 177 are inserted into the shaft hole 171 and the fixing holes 172 of the supporting member 161 and the attachment portion 163 comes into contact with the bottom wall 146. In this case, the one end 162a of the pressing portion 162 is fitted to the first engaging portion 182. That is, the one end 162a of the pressing portion 162 is inserted between the side wall 128 and the claw portion 186.

The other end 162b of the pressing portion 162 deviates from the second engaging portion 183. In other words, the supporting member 161 is close to the bottom wall 146 while being inclined with respect to the side wall 128. Therefore, there is a gap between the pressing portion 162 and the key pads 156A and 156B.

The cutouts 166 connected to the insertion holes 165 are provided in the attachment portion 163. Therefore, the moving supporting member 161 avoids the displacement portions 158 of the key pads 156A and 156B. In this way, it is possible to put the supporting member 161 close to the bottom wall 146 with ease. As described above, the supporting member 161 is temporarily mounted (i.e., temporarily fixed) at the first position P1 which is away from the side wall 128.

Then, as represented by an arrow T1 in FIG. 31, the supporting member 161 is pivoted on the protruding portion 176 (i.e., supporting portion) inserted into the shaft hole 171 (i.e., engaging portion) to the side wall 128. That is, the supporting member 161 is moved from the first position P1 to the second position P2 which is closer to the side wall 128 than the first position P1. Since the fixing hole 172 into which the protruding portion 177 is inserted has an elliptical shape which extends to the pressing portion 162, the supporting member 161 can be pivoted. The supporting member 161 is pivoted in a direction crossing the side wall 128. That is, the supporting portion 174 is fitted to the supporting member 161 such that the supporting member 161 can be pivoted in the direction crossing the side wall 128.

When the supporting member 161 is pivoted, the end 162b of the pressing portion 162 rides over the second engaging portion 183. For example, when the end 162b of the pressing portion 162 presses the second engaging portion 183, the base portion 187 of the second engaging portion 183 is elastically deformed. The second engaging portion 183 with the elastically deformed base portion 187 avoids the pressing portion 162 and the ends 162b of the pressing portion 162 which is pivoted comes into contact with the key pad 156B. In this way, the end 162b of the pressing portion 162 is interposed between the contact portion 157 of the key pad 156B and the claw portion 188 of the second engaging portion 183.

When the end 162b of the pressing portion 162 is fitted to the second engaging portion 183 in this way, the pressing portion 162 is fixed to the fixing portion 181. In this way, the pressing portion 162 presses the contact portions 157 of the key pads 156A and 156B to the side wall 128. That is, while the supporting member 161 is being moved from the first position P1 to the second position P2, the contact portion 157 of the key pad 156B is interposed between the side wall 128 and the pressing portion 162 and is deformed (i.e., compressed and deformed) between the side wall 128 and the pressing portion 162.

Then, the protruding portions 176 and 177 inserted into the shaft hole 171 and the fixing holes 172 are welded to the attachment portion 163. In this way, the attachment portion 163 is fixed to the bottom wall 146 and the supporting member 161 is firmly fixed to the housing 115. That is, the supporting member 161 is fixed (i.e., mainly fixed) to the housing 115 at the second position P2.

According to the television 110 having the above-mentioned structure, similarly to the first embodiment, it is possible to improve the assemblability of the television 110 and reduce the size thereof. For example, in this embodiment, the key pads 156A and 156B covering the openings 147A and 147B are pressed to the side wall 128 by the supporting member 161. In this way, it is possible to prevent liquid, such as water, or dust from getting into the housing 115.

Since the supporting member 161 presses the key pads 156A and 156B, the position of the module board 139 having the switches 141A and 141B mounted thereon is free for the key pads 156A and 156B. In this way, for example, it is not necessary to press the key pads 156A and 156B with a board, such as the module board 139, or divide the housing 115 at the position where the openings 147A and 147B are provided. Therefore, flexibility in the design of the television 110 is improved.

When the user presses the button 131, the pressing force applied to the button 131 acts on the supporting member 161. Since the supporting member 161 receives the pressing force, it is possible to prevent the damage of the module board 139 due to external force.

The module board 139 is arranged so as to intersect the side wall 128. In other words, the module board 139 faces the bottom wall 146. In this way, the module board 139 can be attached to the housing 115 substantially in parallel to the bottom wall 146. Therefore, it is easy to assemble the television 110.

The insertion hole 165 into which a part of the displacement portion 158 of the key pad 156A or 156B is inserted is provided in the pressing portion 162. In this way, even when the pressing portion 162 is interposed between the switches 141A and 141B mounted on the module board 139 and the contact portions 157 of the key pads 156A and 156B, the displacement portion 158 can press the switches 141A and 141B.

The engaging portions 182 and 183 of the fixing portion 181 include the base portions 185 and 187 the claw portions 186 and 188. In this way, a screw is not needed to fix the supporting member 161 and it is possible to reduce the number of components of the television 110 and the manufacturing costs of the television 110. In addition, it is possible to attach the supporting member 161 to a small space and improve flexibility in the design. It is easy to assemble the television 110.

The supporting portion 174 is fitted to the supporting member 161 such that the supporting member 161 can be moved in the direction crossing the side wall 128. In this way, it is easy to attach the supporting member 161. When the supporting member 161 is attached, it is possible to prevent the buckling of the key pads 156A and 156B.

Specifically, when the supporting member 161 contacts the key pads 156A and 156B while being moved in a direction substantially perpendicular to the bottom wall 146, the key pads 156A and 156B are pressed or pulled by the supporting member 161. However, in this embodiment, the supporting member 161 approaches the bottom wall 146 such that a gap is formed between the pressing portion 162 and the key pad 156A or 156B and is pivoted to be fixed to the fixing portion 181. Therefore, it is possible to prevent the key pads 156A and 156B from being pressed or pulled by the supporting member 161. As a result, it is possible to prevent the buckling of the key pads 156A and 156B.

The shaft hole 171 is provided in the extension portion 168 of the supporting member 161. The supporting member 161 can be pivoted on the protruding portion 176 inserted into the shaft hole 171. In this way, when the supporting member 161 is attached to the fixing portion 181, it is possible to prevent shaking.

One supporting member 161 fixed to the fixing portion 181 presses a plurality of key pads 156A and 156B to the side wall 128. In this way, it is possible to reduce the number of components and processes and thus reduce manufacturing costs.

The openings 147A and 147B are provided in the side wall 128. According to the television 110 of this embodiment, the waterproof button 131 can be provided on the side wall of the housing 115. In this embodiment, the openings 147A and 147B are provided in the side wall 128, but the embodiments are not limited thereto. The openings 147A and 147B may be provided in, for example, the bottom wall 146. In this case, the pressing portion 162 of the supporting member 161 faces the bottom wall 146 and the attachment portion 163 is attached to, for example, the side wall 128. That is, the openings 147A and 147B are freely arranged and flexibility in the design of the television 110 is improved.

When the buttons 131 are attached to the openings 147A and 147B, the key pads 156A and 156B are temporarily fixed by the claw portions 186 and 188 of the first and second engaging portions 182 and 183. In this way, it is easy to assemble the television 110.

Next, seventh to tenth embodiments will be described. In these embodiments, a supporting member 161 temporarily mounted (i.e., temporarily fixed) at a first position P1 which is away from a side wall 128 and is supported by a supporting portion 174. The supporting member 161 is moved from the first position P1 to a second position P2 that is closer to the side wall 128 than the first position P1, with being supported by the supporting portion 174, and is fixed (mainly fixed) to a housing 115 at the second position P2.

### Seventh Embodiment

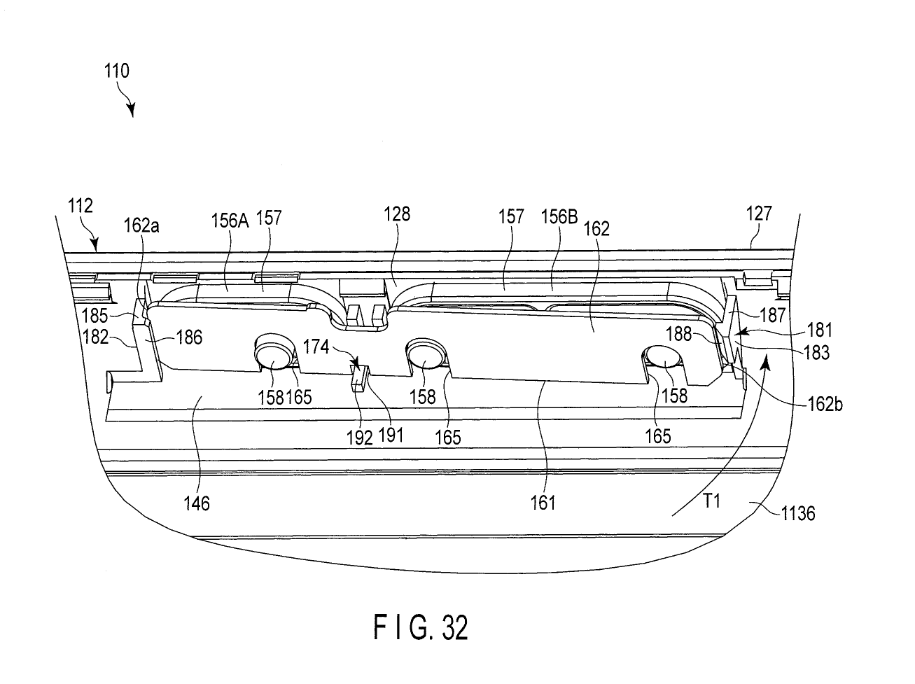

Next, a television 110 according to a seventh embodiment will be described with reference to FIG. 32. In the seventh embodiment, components having the same or similar functions as those in the sixth embodiment are denoted by the same reference numerals and the description thereof will not be repeated. Structures other than the following structures are the same as those in the sixth embodiment.

As shown in FIG. 32, a supporting member 161 according to the seventh embodiment is a flat metal plate. A concave portion 191 (i.e., an engaging portion, a cutout, a groove, a depressed portion, or a slit) is provided at the lower end of the supporting member 161 which faces a bottom wall 146.

A convex portion 192 (i.e., a guide, a guide portion, a protrusion, a rib, or a protruding portion) corresponding to the concave portion 191 is provided on a bottom wall 146. The convex portion 192 is a rib which extends from the bottom wall 146 to the side wall 128. The convex portion 192 is fitted to the concave portion 191 of the supporting member 161 such that the supporting member 161 can be pivoted in a direction crossing the side wall 128.

For example, the supporting member 161 is attached to a fixing portion 181 as follows. First, the convex portion 192 is fitted to the concave portion 191 of the supporting member 161, and an end 162a of the pressing portion 162 is fitted to a first engaging portion 182. Then, the supporting member 161 is pivoted on the end 162a of the pressing portion 162 fitted to the first engaging portion 182. The other end 162b of the pressing portion 162 rides over the second engaging portion 183 and is interposed between a claw portion 188 of a second engaging portion 183 and a contact portion 157 of a key pad 156B. In this way, the supporting member 161 is fixed to the fixing portion 181.

According to the television 110 having the above-mentioned structure, the supporting member 161, which is a flat plate, can press the key pads 156A and 156B to the side wall 128. In this way, it is possible to reduce the size of the supporting member 161 and reduce the material cost of the television 110. In addition, it is possible to ensure a large internal space of the housing 115 and improve flexibility in the design.

### Eighth Embodiment

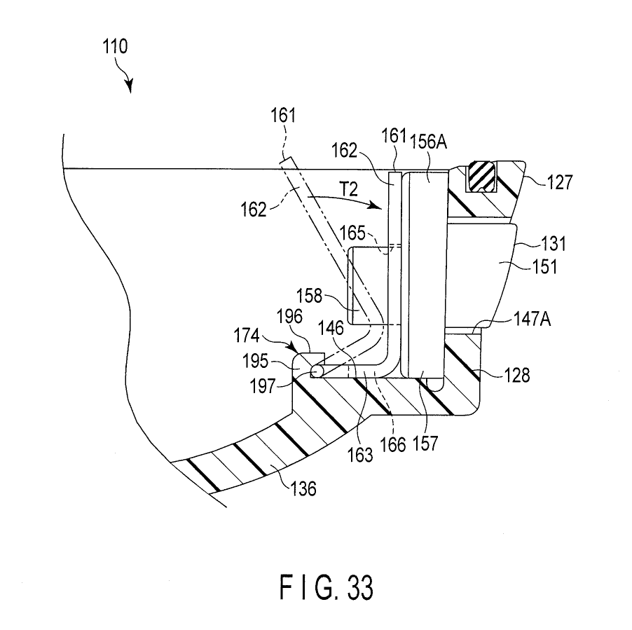

Next, a television 110 according to an eighth embodiment will be described with reference to FIG. 33. In the seventh embodiment, components having the same or similar functions as those in the sixth embodiment are denoted by the same reference numerals and the description thereof will not be repeated. Structures other than the following structures are the same as those in the sixth embodiment.

As shown in FIG. 33, in this embodiment, a pair of supporting portions 174 are provided on the bottom wall 146. Each of the pair of supporting portions 174 includes a base portion 195 (i.e., first portion) which protrudes from a bottom wall 146 and a claw portion 196 (i.e., a second portion or an engaging portion) which extends from the base portion 195 to a side wall 128. The pair of supporting portions 174 comes into contact with both ends of an attachment portion 163 of a supporting member 161 in the longitudinal direction. In other words, the attachment portion 163 is interposed between the pair of supporting portions 174.

The attachment portion 163 of the supporting member 161 includes a pair of shafts 197 (i.e., engaging portions). Each of the pair of shafts 197 is provided at, for example, the end of the attachment portion 163 which is away from the pressing portion 162. The pair of shafts 197 extends in the longitudinal direction of the attachment portion 163 from both ends of the attachment portion 163 in the longitudinal direction. The shaft 197 is fitted to the engaging portion 174.

In this embodiment, base portions 185 and 187 of the first and second engaging portions are formed so as to be elastically deformed. That is, the pressing portion 162 of the supporting member 161 can ride over the first engaging portion 182 and the second engaging portion 183.

For example, the supporting member 161 is attached to the fixing portion 181 as follows. First, the shafts 197 of the attachment portion 163 are fitted to the engaging portions 174. Then, as represented by an arrow T2 in FIG. 33, the supporting member 161 is pivoted on the shaft 197. Both ends 162a and 162b of the pressing portion 162 of the supporting member 161 ride over the first and second engaging portions 182 and 183. In this way, the one end 162a of the pressing portion 162 is interposed between a claw portion 186 of the first engaging portion 182 and a contact portion 157 of a key pad 156A. In addition, the other end 162b of the pressing portion 162 is interposed between a claw portion 188 of the second engaging portion 183 and a contact portion 157 of a key pad 156B. Therefore, the supporting member 161 is fixed to the fixing portion 181.

According to the television 110 having the above-mentioned structure, the supporting member 161 is pivoted on the shaft 197 of the attachment portion 163 which is fitted to the engaging portion 174 provided in the bottom wall 146. In this way, it is possible to fit the supporting member 161 to the engaging portion 174, with the supporting member 161 separated from the key pads 156A and 156B. Therefore, it is possible to prevent the buckling of the key pads 156A and 156B due to the supporting member 161.

### Ninth Embodiment

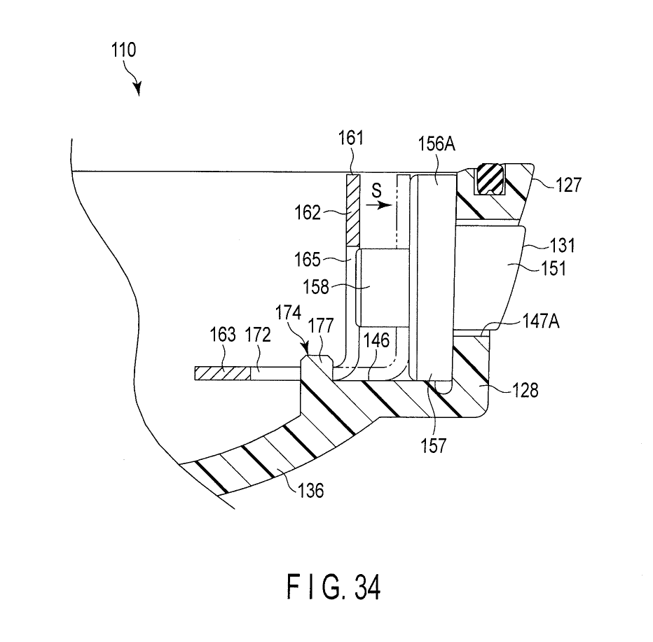

Next, a television 110 according to a ninth embodiment will be described with reference to FIG. 34. In the ninth embodiment, components having the same or similar functions as those in the sixth embodiment are denoted by the same reference numerals and the description thereof will not be repeated. Structures other than the following structures are the same as those in the sixth embodiment.

As shown in FIG. 34, in this embodiment, a supporting portion 174 is provided on a bottom wall 146. In the ninth embodiment, the supporting portion 174 includes a plurality of protruding portions 177. In this embodiment, similarly to the eighth embodiment, base portions 185 and 187 of first and second engaging portions 182 and 183 are formed so as to be elastically deformed.

For example, a supporting member 161 is attached to a fixing portion 181 as follows. First, the supporting member 161 is moved in a direction substantially perpendicular to the bottom wall 146, with being separated from key pads 156A and 156B. Then, a protruding portion 177 is inserted into a fixing hole 172 of the supporting member 161 and the attachment portion 163 comes into contact with the bottom wall 146.

Then, as represented by an arrow S in FIG. 34, the supporting member 161 is moved in a direction substantially perpendicular to a side wall 128 along the fixing hole 172 with an elliptical shape. Both ends 162a and 162b of a pressing portion 162 of the supporting member 161 ride over first and second engaging portions 182 and 183, respectively. In this way, one end 162a of the pressing portion 162 is interposed between a claw portion 186 of the first engaging portion 182 and a contact portion 157 of the key pad 156A. In addition, the other end 162b of the pressing portion 162 is interposed between a claw portion 188 of the second engaging portion 183 and a contact portion 157 of the key pad 156B. Therefore, the supporting member 161 is fixed to the fixing portion 181.

According to the television 110 having the above-mentioned structure, the supporting portion 161 is moved in the direction substantially perpendicular to the side wall 128 and is fixed to the fixing portion 181. In this way, the structure of the television 110 is simplified and the manufacturing costs of the television 110 are reduced.

The supporting member 161 can be moved relative to the bottom wall 146, with being separated from the key pads 156A and 156B. In this way, it is possible to prevent the buckling of the key pads 156A and 156B due to the supporting member 161.

### Tenth Embodiment

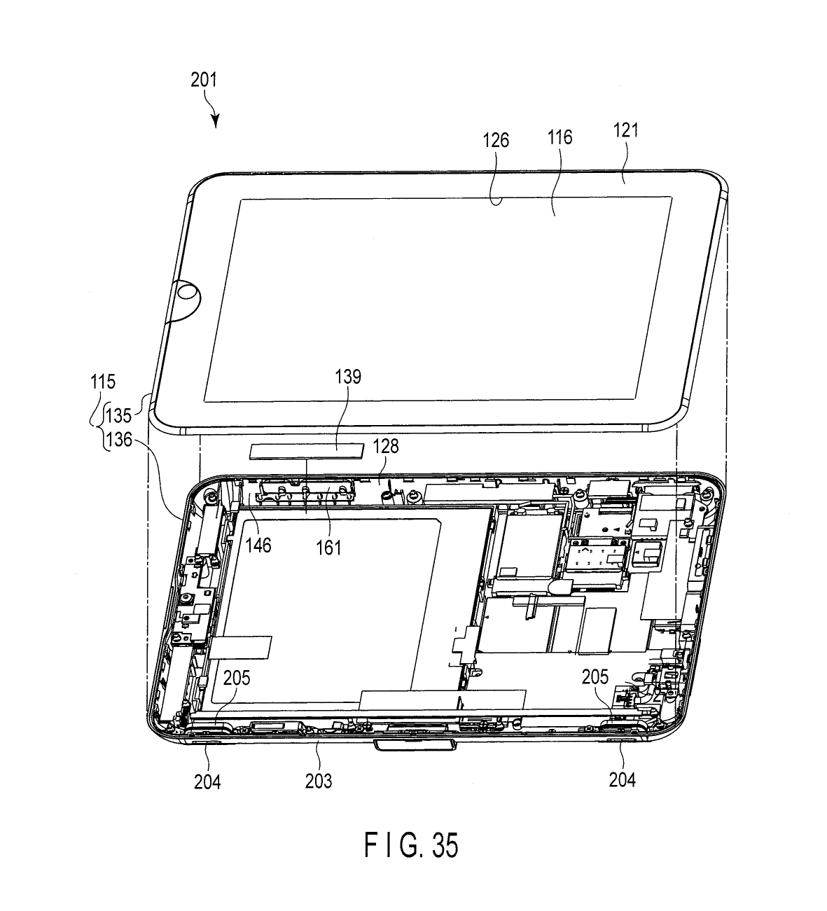

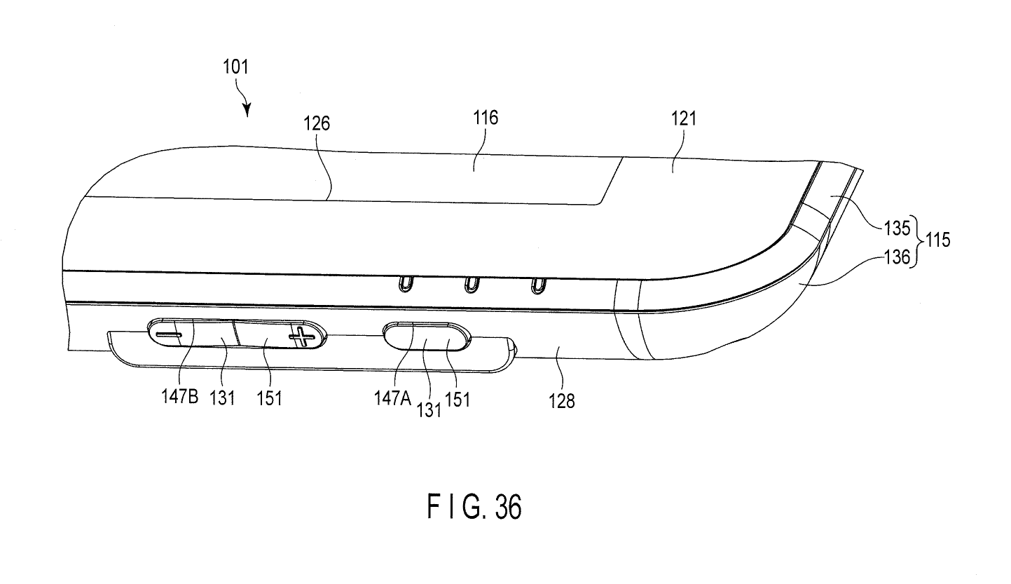

Next, an electronic apparatus according to a tenth embodiment will be described with reference to FIGS. 35 and 36. In the tenth embodiment, components having the same or similar functions as those in the sixth embodiment are denoted by the same reference numerals and the description thereof will not be repeated. Structures other than the following structures are the same as those in the sixth embodiment.

FIG. 35 is an exploded view illustrating a slate computer (a personal computer or a tablet PC) 201 according to the tenth embodiment. The slate computer 201 is an example of an “electronic apparatus”.

As shown in FIG. 35, the slate computer 201 includes a housing 115. The housing 115 includes a front cover 135 forming a front surface 121 of the housing 115 and a rear cover 136. The rear cover 136 includes a side wall 128 forming a side surface of the housing 115, a bottom wall 146 forming the rear surface of the housing 115, and another side wall 203 forming another side surface of the housing 115.

As shown in FIG. 36, a plurality of buttons 131, such as a power button and a volume adjusting button, are provided on the side wall 128. Similarly to the sixth embodiment, the buttons 131 are inserted into openings 147A and 147B provided in the side wall 128 and the openings 147A and 147B are closed by key pads 156A and 156B. The key pads 156A and 156B are pressed to the side wall 128 by a pressing portion 162 of the supporting member 161.

As shown in FIG. 35, the side wall 203 is opposite to the side wall 128. A plurality of openings 204 are provided in the side wall 203. A plurality of speakers 205 are accommodated in the housing 115 so as to correspond to the openings 204. The speaker 205 comes into contact with the side wall 203 from the inside of the housing 115 and closes the corresponding opening 204.

According to the slate computer 201 having the above-mentioned structure, similarly to the sixth embodiment, the key pads 156A and 156B covering the openings 147A and 147B are pressed to the side wall 128 by the supporting member 161. In this way, it is possible to prevent liquid, such as water, or dust from getting into the housing 115.

The position of a module board 139 on which switches 141A and 141B pressed by displacement portions 158 of the key pads 156A and 156B are mounted is free for the key pads 156A and 156B. In this way, for example, the key pads 156A and 156B do not need to be pressed by a board, such as the module board 139, or the housing 115 does not need to be divided at the position where the openings 147A and 147B are provided. Therefore, flexibility in the design of the slate computer 201 is improved.

According to the above-described embodiment, it is possible to improve the assemblability of an electronic apparatus and reduce the size of an electronic apparatus. In addition, the components or members (i.e., all technical ideas) according to all of the above-described embodiments can be combined with each other.

The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a first member comprising a groove along an end of the first member, the groove comprising a bottom;
a second member configured to attach to the first member and to cover the groove;
a sealing member configured to attach to the groove, the sealing member comprising
an annular packing along the end of the first member, the packing configured to be between the first member and the second member, and
protrusions protruding from the packing, and substantially in parallel to the bottom of the groove, and comprising gaps between the protrusions and the bottom of the groove; and
supporting portions on the second member, the supporting portions configured to face the protrusions from a side opposite to the bottom of the groove.

2. The television of claim 1,
wherein the protrusions protrude inward from an inner surface of the annular packing.

3. The television of claim 1,
wherein the packing comprises a first end configured to contact with the bottom of the groove and a second end configured to contact with the second member, and
wherein the sealing member comprises steps between the second end and the protrusions, and the protrusions are configured to be closer to the bottom of the groove than to the second end.

4. The television of claim 3,
wherein the second end of the packing has a wedge shape which is tapered toward the second member.

5. The television of claim 1,
wherein one of the supporting portions is a projection configured to correspond to one of the protrusions and to protrude from the second member toward the one of the protrusions.

6. The television of claim 4,
wherein an end of the projection is configured to be inserted into the groove and to face the one of the protrusions in the groove.

7. The television of claim 1,
wherein the packing comprises a path-changed portion, and
the protrusions are on both sides of the path-changed portion.

8. A television comprising:
a first member;
a second member configured to attach to the first member in a first direction;
an elastic portion comprising
a packing comprising a linear portion configured to be between the first member and the second member, and
protrusions separated from each other in a direction in which the packing extends, the protrusions protruding in a second direction crossing the first direction; and
supporting portions on the second member, the supporting portions configured to face the protrusions from a side opposite to the first member.

9. The television of claim 8,
wherein gaps are between the protrusions and the first member.

10. A television comprising:
an elastic portion comprising a packing and a protrusion on the packing;
a first member comprising a first portion configured to face the protrusion; and
a second member comprising a second portion configured to face the protrusion from a side opposite to the first portion,
wherein the packing is configured to be between the first member and the second member.
